(19) United States
(12) Patent Application Publication
(10) Pub. No.: US 2026/0047193 A1
(43) Pub. Date: Feb. 12, 2026

(54) INTEGRATED CIRCUIT DEVICE

(71) Applicant: Samsung Electronics Co., Ltd., Suwon-si (KR)

(72) Inventors: Youngjin YANG, Suwon-si (KR); Wooseok PARK, Suwon-si (KR); Nakyoung YANG, Suwon-si (KR); Donghoon HWANG, Suwon-si (KR)

(73) Assignee: Samsung Electronics Co., Ltd., Suwon-si (KR)

(21) Appl. No.: 19/271,484

(22) Filed: Jul. 16, 2025

(30) Foreign Application Priority Data
Aug. 6, 2024 (KR) 10-2024-0104731

(51) Int. Cl. H10D 84/83; H01L 23/528; H10D 30/00; H10D 30/01; H10D 64/23; H10D 84/01

(52) U.S. Cl. CPC H10D 84/832; H01L 23/528; H01L 23/5283; H10D 30/502; H10D 64/256; H10D 84/8312; H10D 30/0191; H10D 84/0149

(57) ABSTRACT

An integrated circuit device includes cell transistors at a first vertical level, a front wiring structure at a second vertical level higher than the first vertical level, and a rear wiring structure at a third vertical level lower than the first vertical level. The rear wiring structure includes a device isolation layer arranged on bottom surfaces of the cell transistors, rear contacts arranged in rear contact holes passing through the device isolation layer, a buried interconnector arranged in a recess region that extends into the device isolation layer, connected to a first and second rear contacts, among the rear contacts, and extending in a first horizontal direction or a second horizontal direction, a buried insulating layer arranged in the recess region and arranged on a bottom surface of the buried interconnector, and a rear wiring layer on bottom surfaces of the device isolation layer and the buried insulating layer.

### CROSS-REFERENCE TO RELATED APPLICATION

This application is based on and claims priority under 35 U.S.C. § 119 to Korean Patent Application No. 10-2024-0104731, filed on Aug. 6, 2024, in the Korean Intellectual Property Office, the disclosure of which is incorporated by reference herein in its entirety.

### BACKGROUND

At least some example embodiments of inventive concepts relate to an integrated circuit device, for example to an integrated circuit device including a field-effect transistor (FET) and/or to methods of manufacturing thereof.

As miniaturized, multifunctional, and high-performance electronic products are desired, high-capacity integrated circuit devices may be desired. In order to provide high-capacity integrated circuit devices, increased integration may be advantageous. For example, although small-sized FETs may reduce the area of an integrated circuit, there may a problem of reduced operating speed due to the complexity of wiring structures for small-sized components. Accordingly, in order to achieve functions and operating speeds advantageous for an integrated circuit device, it may be important to design an integrated circuit device in consideration of the degree of integration and performance.

### SUMMARY

The inventive concepts relate to an integrated circuit device including a field effect transistor (FET) and having improved integration and/or electrical performance by including a rear power wiring structure.

According to some example embodiments of inventive concepts, t an integrated circuit device may include a plurality of cell transistors at a first vertical level; a front wiring structure at a second vertical level and electrically connected to the plurality of cell transistors, the second vertical level higher than the first vertical level; and a rear wiring structure at a third vertical level and electrically connected to the plurality of cell transistors, the third vertical level lower than the first vertical level, wherein the rear wiring structure comprises a device isolation layer on bottom surfaces of the plurality of cell transistors; a plurality of rear contacts electrically connected to the plurality of cell transistors and in a plurality of rear contact holes, the plurality of rear contact holes being defined by the device isolation layer; a buried interconnector in a recess region that is at least partially defined by the device isolation layer, the buried interconnector extending in a first horizontal direction or a second horizontal direction and connected to a first rear contact and a second rear contact among the plurality of rear contacts; a buried insulating layer in the recess region and on a bottom surface of the buried interconnector; and a rear wiring layer on a bottom surface of the device isolation layer and on a bottom surface of the buried insulating layer.

According to some example embodiments of inventive concepts, an integrated circuit device may include a plurality of cell transistors including a plurality of semiconductor patterns apart from one another in a vertical direction; a plurality of gate electrodes at least partially surrounding the plurality of semiconductor patterns and extending in a horizontal direction; and a plurality of source/drain regions located on both sides of each of the plurality of gate electrodes; and a rear wiring structure on bottom surfaces of the plurality of cell transistors, the rear wiring structure including a device isolation layer on bottom surfaces of the plurality of cell transistors; a plurality of rear contacts electrically connected to the plurality of cell transistors and in a plurality of rear contact holes, the rear contact holes at least partially defined by the device isolation layer; a buried interconnector in a recess region, the recess region at least partially defined by the device isolation layer, the buried interconnector connected to a first rear contact and to a second rear contact among the plurality of rear contacts; a buried insulating layer in the recess region and on a bottom surface of the buried interconnector; and a rear wiring layer on a bottom surface of the device isolation layer and on a bottom surface of the buried insulating layer.

According to some example embodiments of inventive concepts, an integrated circuit device may include a plurality of semiconductor patterns apart from one another in a vertical direction; a plurality of gate electrodes at least partially surrounding the plurality of semiconductor patterns and extending in a horizontal direction; a plurality of source/drain regions located on both sides of each of the plurality of gate electrodes; a device isolation layer on a bottom surface of the plurality of source/drain regions and a on bottom surface the plurality of gate electrodes; a plurality of rear contacts respectively arranged in a plurality of rear contact holes passing through the device isolation layer, the plurality of rear contacts including a first rear contact connected to a first source/drain region among the plurality of source/drain regions, a second rear contact connected to a second source/drain region among the plurality of source/drain regions, and a third rear contact connected to a first gate electrode among the plurality of gate electrodes; a buried interconnector in a recess region and connected to the first to third rear contacts, the recess region at least partially defined by the device isolation layer, the buried interconnector including a first buried interconnector between the first rear contact and the second rear contact and connected to the first rear contact and the second rear contact, and a second buried interconnector between the first buried interconnector and the third rear contact and connected to the first buried interconnector and the third rear contact; and a buried insulating layer in the recess region and on a bottom surface of the buried interconnector.

### BRIEF DESCRIPTION OF THE DRAWINGS

Example embodiments will be more clearly understood from the following detailed description taken in conjunction with the accompanying drawings in which:

FIG. 1A is a schematic layout diagram illustrating an integrated circuit device according to some example embodiments;

FIG. 1B is a cross-sectional view taken along lines A-A′ and B-B′ of FIG. 1A;

FIG. 1C is a cross-sectional view taken along lines C-C′ and D-D′ of FIG. 1A;

FIG. 1D is a perspective view schematically illustrating some components of the integrated circuit device;

FIG. 1E is an enlarged view of the portion CX1 of FIG. 1B;

FIG. 1F is an enlarged view of the portion CX2 of FIG. 1C;

FIG. 2 is a cross-sectional view of an integrated circuit device according to some example embodiments;

FIG. 3 is a cross-sectional view of an integrated circuit device according to some example embodiments;

FIG. 4 is a cross-sectional view of an integrated circuit device according to some example embodiments;

FIGS. 5A and 5B are cross-sectional views of an integrated circuit device according to some example embodiments;

FIG. 6A is a layout diagram of an integrated circuit device according to some example embodiments;

FIG. 6B is a cross-sectional view taken along lines A-A′ and B-B′ of FIG. 6A;

FIG. 6C is a cross-sectional view taken along line C-C′ of FIG. 6A;

FIG. 7 is a layout diagram of an integrated circuit device according to some example embodiments;

FIG. 8A is a cross-sectional view illustrating an integrated circuit device according to some example embodiments;

FIG. 8B is a perspective view illustrating some components of an integrated circuit device;

FIG. 9A is a cross-sectional view illustrating an integrated circuit device according to some example embodiments;

FIG. 9B is a perspective view illustrating some components of an integrated circuit device;

FIG. 10A is a cross-sectional view illustrating an integrated circuit device according to some example embodiments;

FIG. 10B is a perspective view illustrating some components of an integrated circuit device;

FIG. 11A is a schematic layout diagram illustrating an integrated circuit device according to some example embodiments;

FIG. 11B is a cross-sectional view taken along lines A-A′ and B-B′ of FIG. 11A;

FIG. 11C is a cross-sectional view taken along lines C-C′ and D-D′ of FIG. 11A; and

FIGS. 12A, 12B, 13A, 13B, 14A, 14B, 15A, 15B, 16A, 16B, 17A, 17B, 18A, 18B, 19A, 19B, 20A, 20B, 21A, 21B, 22A, 22B, 23A, 23B, 24A, 24B, 25A, 25B, 26A, 26B, 27A, 27B, 28A, 28B, 29A, 29B, 30A, and 30B are cross-sectional views illustrating a method of manufacturing an integrated circuit device according to some example embodiments.

### DETAILED DESCRIPTION

Hereinafter, some example embodiments of the inventive concepts will be described in detail with reference to the accompanying drawings.

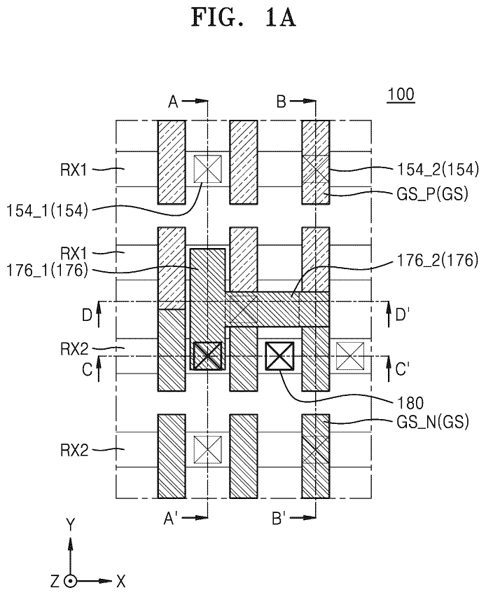

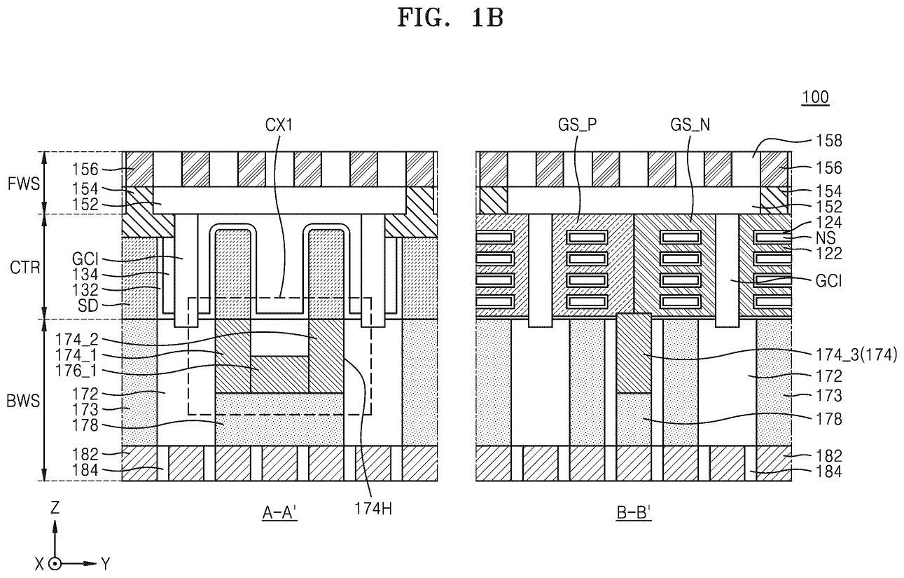

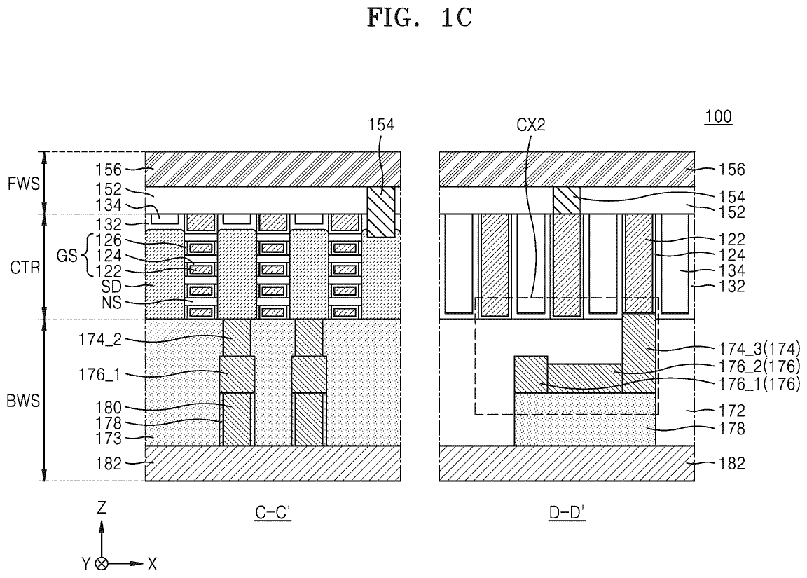

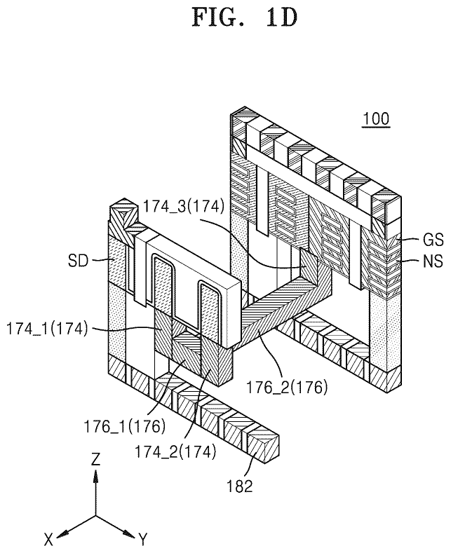

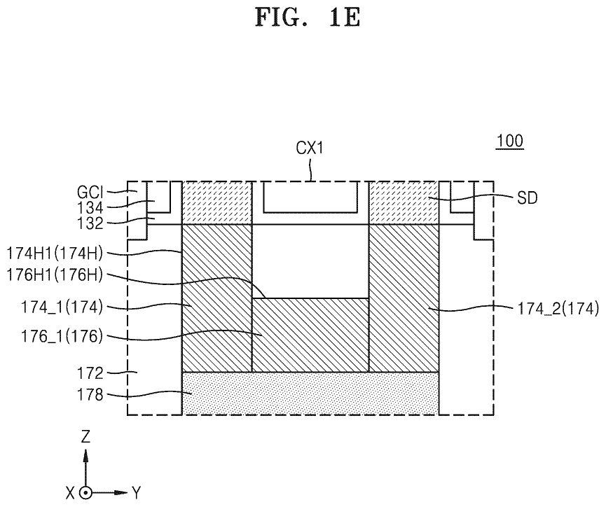

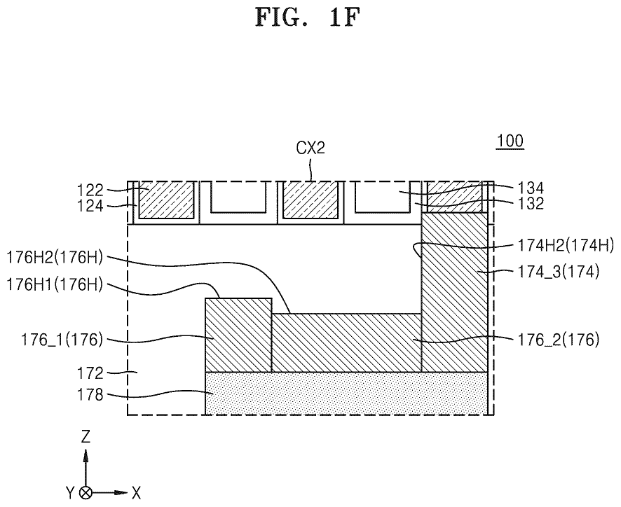

FIG. 1A is a schematic layout diagram illustrating an integrated circuit device 100 according to some example embodiments. FIG. 1B is a cross-sectional view taken along lines A-A′ and B-B′ of FIG. 1A. FIG. 1C is a cross-sectional view taken along lines C-C′ and D-D′ of FIG. 1A. FIG. 1D is a perspective view schematically illustrating some components of the integrated circuit device 100. FIG. 1E is an enlarged view of the portion CX1 of FIG. 1B. FIG. 1F is an enlarged view of the portion CX2 of FIG. 1C.

Referring to FIGS. 1A to 1F, the integrated circuit device 100 may include a plurality of cell transistors CTR at a first vertical level, a front wiring structure FWS at a second vertical level higher than the first vertical level and electrically connected to the plurality of cell transistors CTR, and a rear wiring structure BWS at a third vertical level lower than the first vertical level and electrically connected to the plurality of cell transistors CTR.

Each of the plurality of cell transistors CTR may constitute various types of logic cells included in a logic circuit. For example, in some example embodiments relating to FIGS. 1A to 1F, the integrated circuit device 100 may constitute a logic cell including a multi-bridge channel field effect transistor (FET) (MBCFET) device. However, example embodiments are not limited thereto, and the integrated circuit device 100 may include a planar FET device, a gate-all-around type FET device, a finFET device, and a two-dimensional material-based FET device such as, for example, a MoS₂ semiconductor gate electrode.

The integrated circuit device 100 may include a first active region RX1 and a second active region RX2 extending in a first horizontal direction X. In some example embodiments related to FIG. 1A, the first active region RX1 may be or include a p-type metal oxide semiconductor (PMOS) transistor region, and the second active region RX2 may be or include an n-type metal oxide semiconductor (NMOS) transistor region. For example, the plurality of cell transistors CTR arranged in the first active region RX1 may include a PMOS transistor, and the plurality of cell transistors CTR arranged in the second active region RX2 may include an NMOS transistor.

The plurality of cell transistors CTR may be apart from one another in the first horizontal direction X and a second horizontal direction Y. The plurality of cell transistors CTR may include a plurality of semiconductor patterns NS apart from one another in a vertical direction Z, a plurality of gate structures GS surrounding the plurality of semiconductor patterns NS and extending in the second horizontal direction Y, and a plurality of source/drain regions SD each two of which are arranged on both sides of each of the plurality of gate structures GS.

In some example embodiments, each of the plurality of semiconductor patterns NS may include, for example, a group IV semiconductor such as silicon (Si) or germanium (Ge), a group IV-IV compound semiconductor such as silicon germanium (SiGe) or silicon carbide (SiC), or a group III-V compound semiconductor such as gallium arsenide (GaAs), indium arsenide (InAs), or indium phosphide (InP).

In some example embodiments, the plurality of gate structures GS may extend in the second horizontal direction Y to surround or at least partially surround the plurality of semiconductor patterns NS and may be apart from one another in the first horizontal direction X.

In some example embodiments, each of the plurality of gate structures GS may include a gate electrode 122, a gate insulating layer 124, and a gate spacer 126. For example, the gate electrode 122 may extend in the second horizontal direction Y to surround or at least partially surround the plurality of semiconductor patterns NS, and the gate insulating layer 124 may be arranged between the gate electrode 122 and each of the plurality of semiconductor patterns NS. Gate spacers 126 may be arranged on both sidewalls of the gate electrode 122.

In some example embodiments, the gate electrode 122 may include, for example, doped polysilicon, a metal, a conductive metal nitride, a conductive metal carbide, a conductive metal silicide, or any combination thereof. For example, the gate electrode 122 may include aluminum (Al), copper (Cu), titanium (Ti), tantalum (Ta), tungsten (W), molybdenum (Mo), tantalum nitride (TaN), nickel silicide (NiSi), cobalt silicide (CoSi), titanium nitride (TiN), tungsten nitride (WN), titanium aluminide (TiAl), TiAlN, TaCN, tantalum carbide (TaC), TaSiN, or a combination thereof. However, example embodiments are not limited thereto. In some example embodiments, the gate electrode 122 may include a work function metal-containing layer and a gap-fill metal layer. The work function metal-containing layer may include, for example, at least one metal selected from Ti, W, ruthenium (Ru), niobium (Nb), Mo, hafnium (Hf), nickel (Ni), cobalt (Co), platinum (Pt), ytterbium (Yb), terbium (Tb), dysprosium (Dy), erbium (Er), and palladium (Pd), but example embodiments are not limited thereto. The gap-fill metal layer may include a W layer or an Al layer. In some example embodiments, the gate electrode 150 may include a stacked structure of TiAlC/TiN/W, a stacked structure of TiN/TaN/TiAlC/TiN/W, or a stacked structure of TiN/TaN/TiN/TiAlC/TiN/W. However, example embodiments are not limited thereto.

In some example embodiments, the gate insulating layer 124 may include, for example, a silicon oxide layer, a silicon oxynitride layer, a high-k dielectric layer having a higher dielectric constant than the silicon oxide layer, or a combination thereof. The high-k dielectric layer may include, for example, metal oxide or metal oxynitride. For example, the high-k dielectric layer that may be used as the gate insulating layer 124 may include HfO₂, HfSiO, HfSiON, HfTaO, HfTiO, HfZrO, ZrO₂, Al₂O₃, or a combination thereof. However, example embodiments are not limited thereto.

In some example embodiments, the gate spacer 126 may include silicon oxide (SiOₓ), silicon nitride (SiNₓ), silicon oxynitride (SiOₓN_{y}), silicon carbon nitride (SiCₓN_{y}), silicon oxycarbon nitride (SiOₓC_{y}N_{z}), or a combination thereof.

Source/drain regions SD may be formed on both sides of the gate structure GS. The source/drain region SD may be connected to both ends of each of the plurality of semiconductor patterns NS. The source/drain region SD may have a top surface at a higher level than a top surface of the uppermost semiconductor pattern NS.

In some example embodiments, the source/drain region SD may include a doped SiGe layer, a doped Ge layer, a doped SiC layer, or a doped InGaAs layer. However, example embodiments are not limited thereto. In some example embodiments, the source/drain region SD may include a plurality of semiconductor layers with different compositions. For example, the source/drain region SD may include a lower semiconductor layer, an upper semiconductor layer, and a capping semiconductor layer, which are sequentially stacked. For example, the lower semiconductor layer, the upper semiconductor layer, and the capping semiconductor layer each may include SiC and may have different contents of Si and C.

The cell transistor CTR may include an NMOS transistor or a PMOS transistor according to a conductivity type of the semiconductor pattern NS and/or a conductivity type of the source/drain region SD.

In some example embodiments, the plurality of cell transistors CTR arranged in the first active region RX1 may include a PMOS transistor, and the gate electrode 122 arranged in the first active region RX1 may include a p-type gate electrode GS_P. For example, the gate electrode 122 surrounding or at least partially surrounding the plurality of semiconductor patterns NS arranged in the first active region RX1 and extending in the second horizontal direction Y may be referred to as the p-type gate electrode GS_P.

In some example embodiments, the plurality of cell transistors CTR arranged in the second active region RX2 may include an NMOS transistor, and the gate electrode 122 arranged in the second active region RX2 may include an n-type gate electrode GS_N. For example, the gate electrode 122 surrounding or at least partially surrounding the plurality of semiconductor patterns NS arranged in the second active region RX2 and extending in the second horizontal direction Y may be referred to as the n-type gate electrode GS_N.

In some example embodiments, the p-type gate electrode GS_P and the n-type gate electrode GS_N may include different materials. In other example embodiments, the p-type gate electrode GS_P and the n-type gate electrode GS_N may include the same material(s). In some example embodiments, as illustrated in FIGS. 1A and 1B, the n-type gate electrode GS_N and the p-type gate electrode GS_P may be arranged adjacent to each other in the second horizontal direction Y.

An insulating liner 132 and an inter-gate insulating layer 134 covering the source/drain region SD may be formed between the gate structures GS. The insulating liner 132 and the inter-gate insulating layer 134 may include, for example, silicon oxide or silicon oxynitride.

A gate cut insulating layer GCI may be arranged between two gate structures GS adjacent to each other in the second horizontal direction Y. In some example embodiments, the gate cut insulating layer GCI may extend in the first horizontal direction X.

The front wiring structure FWS may be arranged on the cell transistor CTR and the gate cut insulating layer GC. The front wiring structure FWS may include an upper insulating layer 152, a front contact 154, a front wiring layer 156, and a front insulating layer 158. In some example embodiments, the front wiring layer 156 may be a wiring pattern at one vertical level or wiring patterns at two or more vertical levels.

In some example embodiments, the upper insulating layer 152 and the front insulating layer 158 may include an oxide layer, a nitride layer, a low-k dielectric layer having a dielectric constant of about 2.2 to about 2.4, or a combination thereof. The front contact 154 may be arranged on a top surface of the source/drain region SD or the gate electrode 122. For example, as illustrated in FIG. 1A, the front contact 154 may include a first front contact 1541 arranged on the source/drain region SD and a second front contact 154_2 arranged on the gate electrode 122, but example embodiments are not limited thereto. The front wiring layer 156 may be arranged on a top surface of the front contact 154, and sidewalls of the front wiring layer 156 may be surrounded or at least partially surrounded by the front insulating layer 158.

The rear wiring structure BWS may be arranged under the cell transistor CTR and the gate cut insulating layer GC. The rear wiring structure BWS may include a power delivery network for applying a power supply voltage and a ground voltage to the cell transistor CTR. The rear wiring structure BWS may include a first device isolation layer 172, a second device isolation layer 173, a rear contact 174, a buried interconnector 176, a buried insulating layer 178, a rear via 180, a rear wiring layer 182, and a rear insulating layer 184.

In some example embodiments, the first device isolation layer 172 and the second device isolation layer 173 may be arranged on a bottom surface of the cell transistor CTR. For example, the second device isolation layer 173 may extend in the vertical direction Z at a position vertically overlapping or at least partially overlapping with the source/drain region SD and the plurality of semiconductor patterns NS. For example, the second device isolation layer 173 may extend in the first horizontal direction X at a position vertically overlapping or at least partially overlapping with the first active region RX1 and the second active region RX2, and the first device isolation layer 172 may extend in the first horizontal direction X at a position between the first active region RX1 and the second active region RX2.

In some example embodiments, the first device isolation layer 172 may include silicon oxide, and the second device isolation layer 173 may include an oxide layer, a nitride layer, a low-k dielectric layer having a dielectric constant of about 2.2 to about 2.4, or a combination thereof, but example embodiments are not limited thereto.

The rear contact 174 may be arranged in a rear contact hole 174H passing through (for example, defined or at least partially defined by) the first device isolation layer 172 or the second device isolation layer 173. The rear contact 174 may be electrically connected to the cell transistor CTR. For example, the rear contact 174 may be connected to a bottom surface of the source/drain region SD or a bottom surface of the gate electrode 122.

In some example embodiments, as illustrated in FIG. 1B, the rear contact 174 may include a first rear contact 174_1, a second rear contact 174_2, and a third rear contact 174_3, the first rear contact 174_1 may be electrically connected to one source/drain region SD (for example, the first source/drain region), and the second rear contact 174_2 may be electrically connected to the other source/drain region SD (for example, the second source/drain region) apart from the one source/drain region SD in the second horizontal direction Y, and the third rear contact 174_3 may be electrically connected to the gate electrode 122.

In some example embodiments, the third rear contact 174_3 may be commonly connected to the n-type gate electrode GS_N and the p-type gate electrode GS_P. In other example embodiments, the third rear contact 174_3 may be connected to either the n-type gate electrode GS_N or the p-type gate electrode GS_P.

In some example embodiments, the rear contact hole 174H may include a first rear contact hole 174H1 and a second rear contact hole 174H2, the first rear contact hole 174H1 may expose the bottom surface of the source/drain region SD through the first device isolation layer 172, and the second rear contact hole 174H2 may expose the bottom surface of the gate electrode 122 through the first device isolation layer 172. The first rear contact 174_1 and the second rear contact 174_2 may be arranged in the first rear contact hole 174H1, and the third rear contact 174_3 may be arranged in the second rear contact hole 174H2.

A recess region 176H may be connected to the rear contact hole 174H and may extend into (for example, be defined or at least partially defined by) the first device isolation layer 172. The buried interconnector 176 may be arranged in the recess region 176H and may be connected to the rear contact 174. In some example embodiments, the buried interconnector 176 may extend in the first horizontal direction X or the second horizontal direction Y, and may electrically connect at least two of the plurality of rear contacts 174 to each other. In some example embodiments, the buried interconnector 176 may be apart from the bottom surface of the source/drain region SD and/or the bottom surface of the gate electrode 122 in the vertical direction Z.

In some example embodiments, as illustrated in FIG. 1B, a first buried interconnector 176_1 may connect the first rear contact 174_1 to the second rear contact 174_2, and may extend in the second horizontal direction Y. In some example embodiments, as illustrated in FIG. 1B, a second buried interconnector 176_2 may connect the first buried interconnector 176_1 to the third rear contact 174_3, and may extend in the first horizontal direction X.

The first buried interconnector 176_1 and the second buried interconnector 176_2 illustrated in FIG. 1D may collectively have a T-shaped horizontal cross-sectional shape. The first buried interconnector 1761 may indicate a part of the buried interconnector 176 extending in the second horizontal direction Y, and the second buried interconnector 176_2 may indicate a part of the line-shaped buried interconnector 176 extending in the first horizontal direction X. In some example embodiments, the first buried interconnector 176_1 may be arranged in the first recess region 176H1, and the second buried interconnector 1762 may be arranged in the second recess region 176H2.

In some example embodiments, the first buried interconnector 176_1 may enable electrical connection between two source/drain regions SD (for example, the first source/drain region and the second source/drain region) apart from each other in the second horizontal direction Y, and the second buried interconnector 176_2 may enable electrical connection between two components apart from each other in the first horizontal direction X, for example, between the source/drain region SD and the gate electrode 122.

In some example embodiments, an upper surface level of the first buried interconnector 176_1 may be higher than an upper surface level of the second buried interconnector 176_2. For example, a distance between a top surface of the first buried interconnector 176_1 and the bottom surface of the source/drain region SD may be less than a distance between a top surface of the second buried interconnector 176_2 and the bottom surface of the gate electrode 122. In other words, a height of the first device isolation layer 172 arranged between the top surface of the first buried interconnector 176_1 and the bottom surface of the source/drain region SD in the vertical direction Z may be less than a height of the first device isolation layer 172 arranged between the top surface of the second buried interconnector 176_2 and the bottom surface of the gate electrode 122 in the vertical direction Z.

In some example embodiments, a bottom surface of the buried interconnector 176 may be arranged on the same plane as (or coplanar with) a bottom surface of the rear contact 174. For example, bottom surfaces of the first buried interconnector 176_1, the second buried interconnector 176_2, the first rear contact 174_1, the second rear contact 1742, and the third rear contact 174_3 may be arranged on the same plane (or coplanar with one another).

In some example embodiments, the top surfaces of the first buried interconnector 176_1 and the second buried interconnector 176_2 may be at a lower vertical level than top surfaces of the first device isolation layer 172 and the second device isolation layer 173, and the bottom surfaces of the first buried interconnector 176_1 and the second buried interconnector 176_2 may be at a higher vertical level than bottom surfaces of the first device isolation layer 172 and the second device isolation layer 173. Heights of the first buried interconnector 176_1 and the second buried interconnector 176_2 in the vertical direction Z may be less than heights of the first device isolation layer 172 and the second device isolation layer 173 in the vertical direction Z.

The buried insulating layer 178 may be arranged in the rear contact hole 174H and the recess region 176H and on the bottom surfaces of the rear contact 174 and the buried interconnector 176. A top surface of the buried insulating layer 178 may contact the bottom surfaces of the rear contact 174 and the buried interconnector 176, and side surfaces of the buried insulating layer 178 may contact the first device isolation layer 172. In some example embodiments, the top surface of the buried insulating layer 178 contacting the bottom surfaces of the rear contact 174 and the buried interconnector 176 may have a flat profile.

In some example embodiments, the rear contact 174 and the buried interconnector 176 may include at least one of W, Co, Mo, Ni, Ru, Cu, Al, silicide thereof, or an alloy thereof, but example embodiments are not limited thereto. In some example embodiments, the buried insulating layer 178 may include an oxide layer, a nitride layer, a low dielectric constant insulating layer, or a combination thereof. In some example embodiments, the buried insulating layer 178 may include a low dielectric constant insulating layer including at least one of carbon-containing silicon oxide, carbon-containing silicon oxynitride, carbon-containing silicon nitride, or silicon carbon boron nitride.

In some example embodiments, a conductive barrier layer surrounding or at least partially surrounding top and side surfaces of the rear contact 174 and the buried interconnector 176 may be further formed, and the conductive barrier layer may include, for example, at least one of Ru, Ti, TiN, Ta, TaN, W, titanium silicon nitride (TiSiN), titanium silicide (TiSi), and tungsten silicide (WSi), but example embodiments are not limited thereto.

In some example embodiments, a metal silicide layer may be further arranged between the bottom surface of the source/drain region SD and the rear contact 174.

The rear via 180 may contact the bottom surface of the rear contact 174 or the buried interconnector 176. The rear wiring layer 182 may be arranged on bottom surfaces of the first device isolation layer 172, the second device isolation layer 173, the rear via 180, and the buried insulating layer 178. The rear wiring layer 182 may be electrically connected to the rear contact 174 through the rear via 180, or may be electrically connected to the rear contact 174 through the rear via 180 and the buried interconnector 176. The rear insulating layer 184 may be arranged in a space between the rear wiring layers 182.

In some example embodiments, a top surface of the rear wiring layer 182 may be apart from the bottom surface of the buried interconnector 176 in a vertical direction, and at least a part of the buried insulating layer 178 may be arranged between the bottom surface of the buried interconnector 176 and the top surface of the rear wiring layer 182.

As scale-down of an integrated circuit device progresses, a device structure, in which a front wiring structure for signal transmission is arranged on a top surface of a cell transistor and a rear wiring structure for applying power voltage and ground voltage is arranged on a bottom surface of the cell transistor, has been proposed. However, as a rear device isolation layer needs to be formed to a relatively large thickness for stable operation of peripheral circuit elements such as diodes, a routing length between a rear wiring structure and a cell transistor increases, resulting in a problem of deterioration of device performance.

However, in the integrated circuit device according to some example embodiments, the buried interconnector 176 may be formed in the recess region 176H to provide electrical connection between at least two rear contacts 174. Accordingly, although the first device isolation layer 172 is formed to a relatively large thickness, shortened wiring routing may be implemented through the buried interconnector 176. In addition, the buried interconnector 176 may be used in the rear wiring structure BWS to provide electrical connection between components (for example, between the source/drain region SD and the gate electrode 122, or between two adjacent source/drain regions SD). Accordingly, a freedom of routing (or routability) of the front wiring structure FWS may be improved. Accordingly, the integrated circuit device 100 may have relatively higher electrical performance.

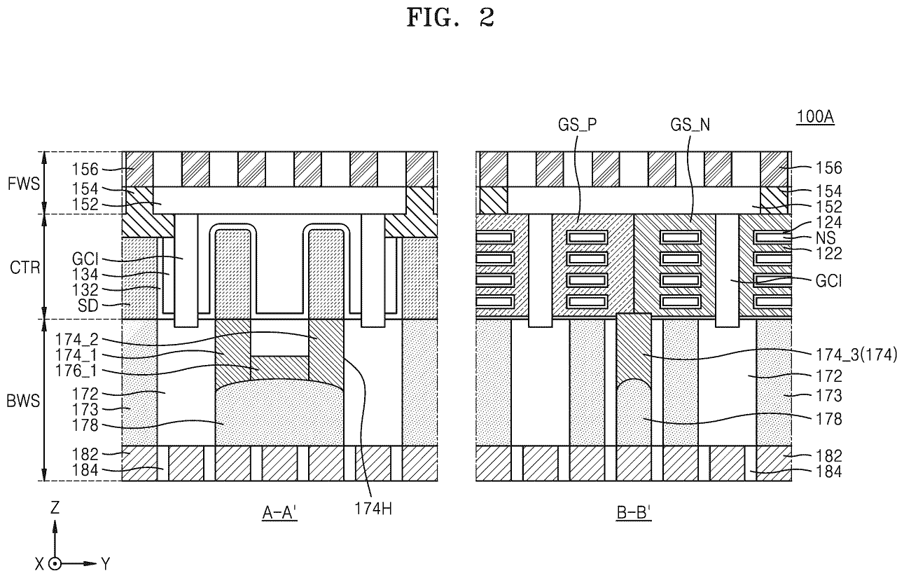

FIG. 2 is a cross-sectional view of an integrated circuit device 100A according to some example embodiments. Specifically, FIG. 2 is a cross-sectional view corresponding to a cross-section taken along lines A-A′ and B-B′ of FIG. 1A. In FIG. 2, the same reference numerals as those of FIGS. 1A to 1F may denote the same components.

Referring to FIG. 2, a bottom surface of a buried interconnector 176 may have a curved shape and may be recessed upward (or recessed toward an inside of the buried interconnector 176). In some example embodiments, a conductive layer may be formed by using a metal material in the recess region 176H, and a recess process may be performed on the conductive layer to reduce a height of the conductive layer. In the recess process, the bottom surface of the buried interconnector 176 may have a curved shape.

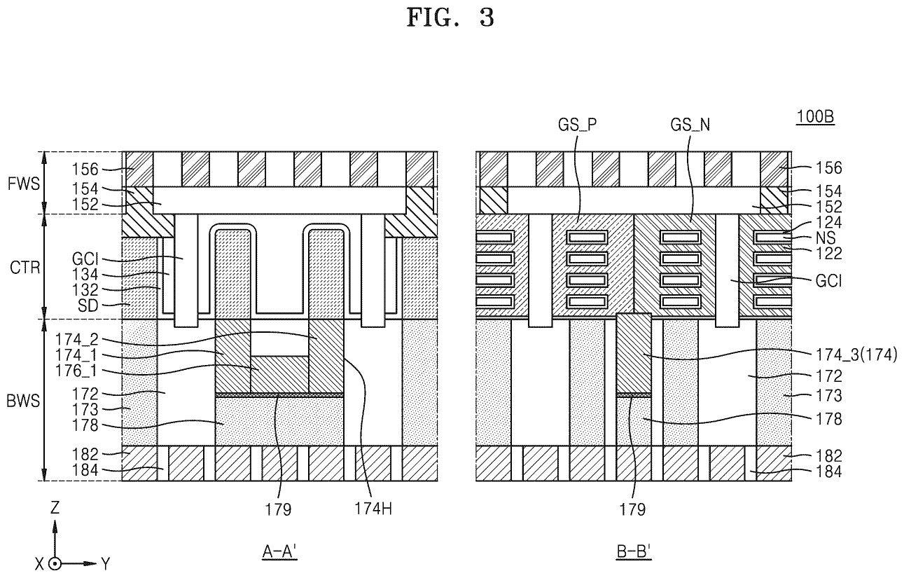

FIG. 3 is a cross-sectional view of an integrated circuit device 100B according to some example embodiments. Specifically, FIG. 3 is a cross-sectional view corresponding to a cross-section taken along lines A-A′ and B-B′ of FIG. 1A. In FIG. 3, the same reference numerals as those of FIGS. 1A to 1F may denote the same components.

Referring to FIG. 3, a capping conductive layer 179 may be arranged on bottom surfaces of a rear contact 174 and a buried interconnector 176. As the capping conductive layer 179 is arranged on the bottom surfaces of the rear contact 174 and the buried interconnector 176, a buried insulating layer 178 may not directly contact the bottom surface of the rear contact 174 and the bottom surface of the buried interconnector 176.

In some example embodiments, the capping conductive layer 179 may include at least one of W, Co, Mo, Ni, Ru, Cu, Al, TiN, and WN.

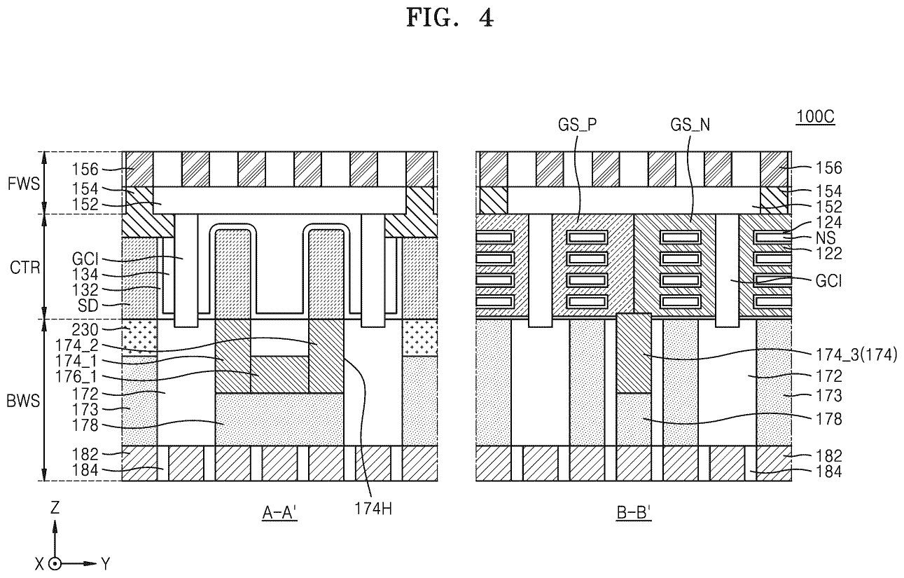

FIG. 4 is a cross-sectional view of an integrated circuit device 100C according to some example embodiments. Specifically, FIG. 4 is a cross-sectional view corresponding to a cross-section taken along lines A-A′ and B-B′ of FIG. 1A. In FIG. 4, the same reference numerals as those of FIGS. 1A to 1F may denote the same components.

Referring to FIG. 4, a placeholder 230 may be arranged on a bottom surface of a source/drain region SD. In some example embodiments, the placeholder 230 may be arranged between the source/drain region SD and a second device isolation layer 173. In some example embodiments, the placeholder 230 may include a semiconductor material and/or an insulating material (for example, SiGe, SiN, or SiBCN). In some example embodiments, the placeholder 230 may include SiGe.

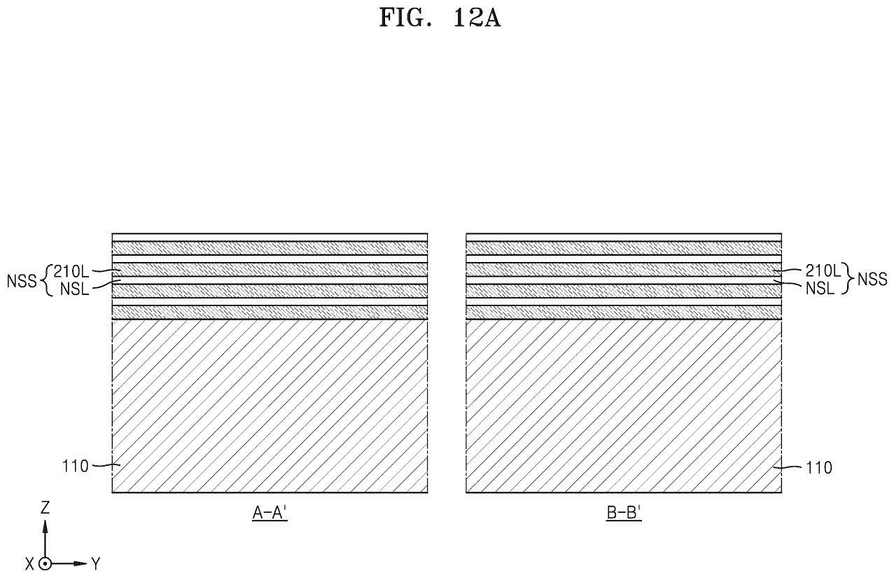

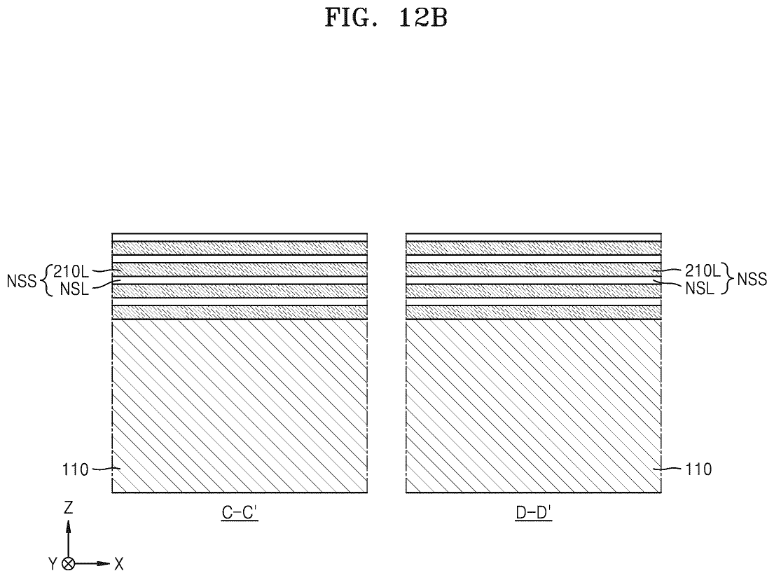

In some example embodiments, the placeholder 230 may be used to form a self-aligned rear contact 174. In some example embodiments, a part of the substrate 110 (refer to FIG. 12A) may be removed to form the placeholder 230 in a portion from which the substrate 110 is removed, and then the source/drain region SD may be formed on the placeholder 230. When a rear surface of the substrate 110 is ground and removed after forming the cell transistor CTR and the front wiring structure FWS, some placeholders 230 at positions in which the rear contact 174 is to be formed may be removed and replaced with the rear contact 174, and some placeholders 230 at positions in which the rear contact 174 is not formed may remain without being removed.

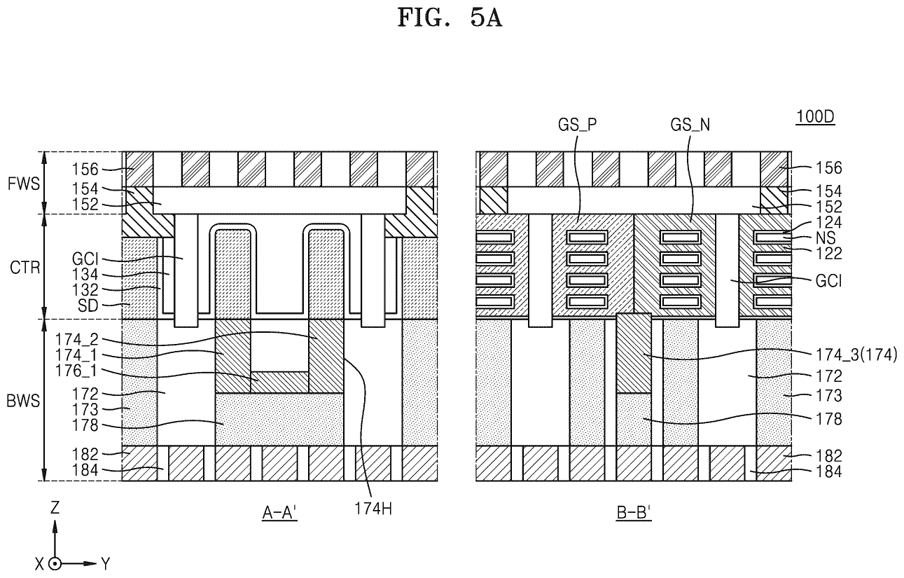

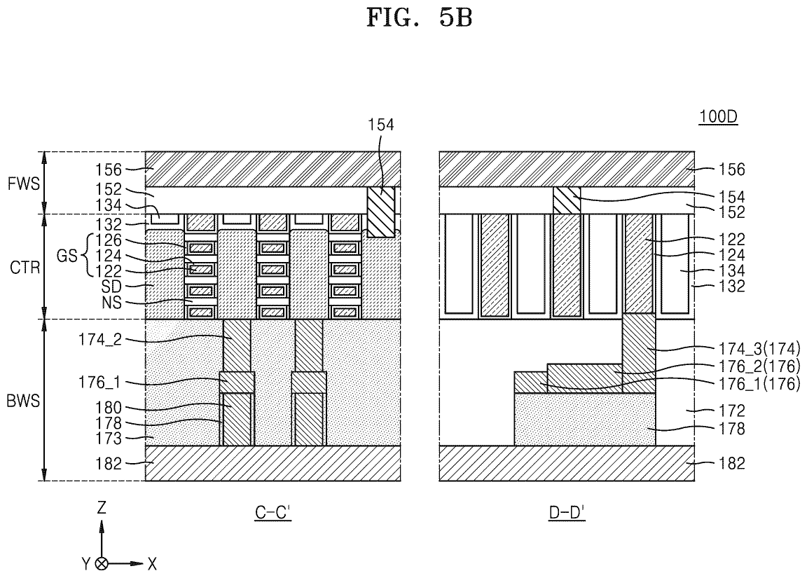

FIGS. 5A and 5B are cross-sectional views of an integrated circuit device 100D according to some example embodiments. Specifically, FIG. 5A is a cross-sectional view corresponding to a cross-section taken along lines A-A′ and B-B′ of FIG. 1A and FIG. 5B is a cross-sectional view corresponding to a cross-section taken along lines C-C′ and D-D′ of FIG. 1A.

Referring to FIGS. 5A and 5B, a top surface of a first buried interconnector 176_1 connecting a first rear contact 174_1 to a second rear contact 1742 may be at a lower level than a top surface of a second buried interconnector 176_2. For example, a distance between the top surface of the first buried interconnector 176_1 and a source/drain region SD in the vertical direction Z may be greater than a distance between the top surface of the second buried interconnector 176_2 and a bottom surface of a gate electrode 122 in the vertical direction Z.

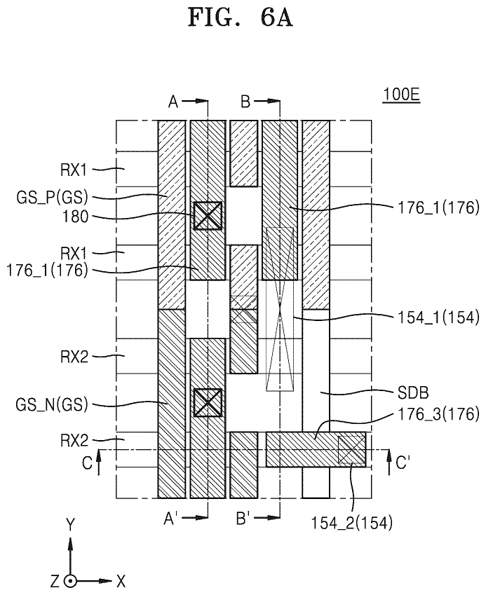

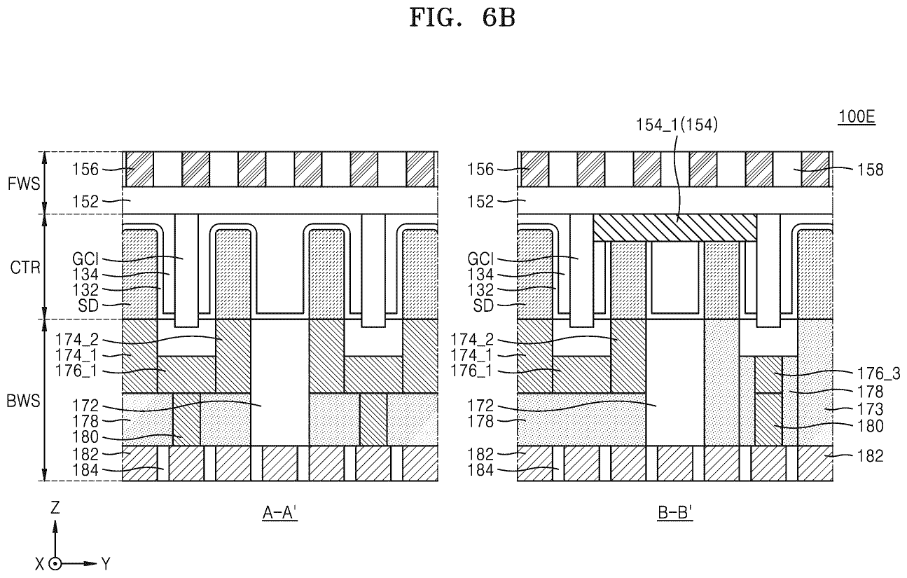

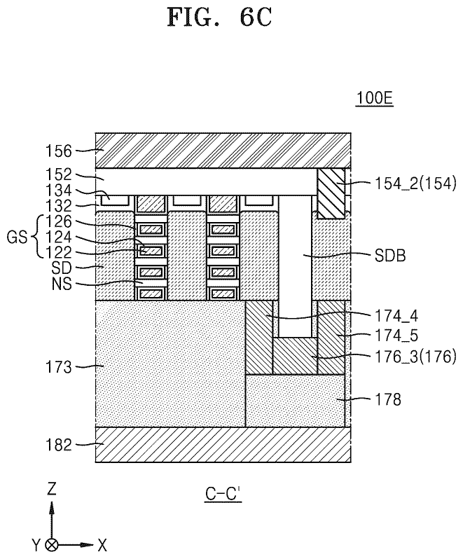

FIG. 6A is a layout diagram of an integrated circuit device 100E according to some example embodiments. FIG. 6B is a cross-sectional view taken along lines A-A′ and B-B′ of FIG. 6A and FIG. 6C is a cross-sectional view taken along line C-C′ of FIG. 6A.

Referring to FIGS. 6A to 6C, two source/drain regions SD adjacent to each other in the second horizontal direction Y may be electrically connected to each other by a first rear contact 174_1, a first buried interconnector 176_1, and a second rear contact 174_2, and the same voltage may be applied to the two source/drain regions SD through a rear via 180 connected to a bottom surface of the first buried interconnector 176_1.

In some example embodiments, as illustrated in a cross-section taken along line A-A′ of FIG. 6B, the two source/drain regions SD adjacent to each other in the second horizontal direction Y may be electrically connected to each other by the first rear contact 174_1, the first buried interconnector 176_1, and the second rear contact 174_2, and the same voltage may be applied to the two source/drain regions SD through the rear via 180 connected to the bottom surface of the first buried interconnector 176_1.

In some example embodiments, as illustrated in a cross-section taken along line B-B′ of FIG. 6B, among three source/drain regions SD adjacent to one another in the second horizontal direction Y, a first source/drain region and a second source/drain region may be electrically connected to each other by the first rear contact 174_1, the first buried interconnector 176_1, and the second rear contact 174_2, and the second source/drain region and a third source/drain region may be electrically connected to each other by a first front contact 154_1. According to such a configuration, an output signal from one device may be applied as an input signal of another device. For example, a common output voltage from the first source/drain region and the second source/drain region may be provided as an input voltage to the third source/drain region through the first front contact 154_1. Alternatively, an output voltage from the third source/drain region may be provided as a common input voltage to the first source/drain region and the second source/drain region through the first front contact 154_1.

In some example embodiments, as illustrated in a cross-section taken along line C-C′ of FIG. 6B, a device isolation structure SDB may be arranged between two source/drain regions SD adjacent to each other in the first horizontal direction X. The device isolation structure SDB may be formed by removing at least part of a gate structure GS and filling an insulating material at a position from which the gate structure GS is removed. For example, the device isolation structure SDB may extend in the second horizontal direction Y and may be arranged in a straight line with the gate structure GS.

The two source/drain regions SD adjacent to each other in the first horizontal direction X with the device isolation structure SDB therebetween may be electrically connected to each other by a fourth rear contact 174_4, a third buried interconnector 176_3, and a fifth rear contact 174_5. For example, the third buried interconnector 176_3 may be arranged between the fourth rear contact 174_4 and the fifth rear contact 174_5 and may contact a bottom surface of the device isolation structure SDB.

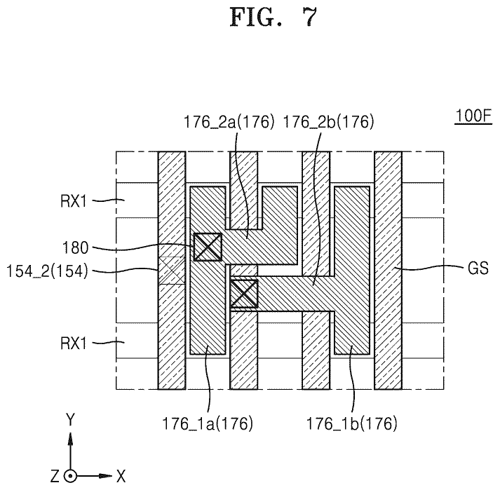

FIG. 7 is a layout diagram of an integrated circuit device 100F according to some example embodiments.

Referring to FIG. 7, at least two buried interconnectors 176 may be arranged in the second horizontal direction Y between two adjacent first active regions RX1. For example, a first buried interconnector 176_1a extending in the second horizontal direction Y may be arranged between two adjacent gate structures GS, and a second buried interconnector 176_1b extending in the second horizontal direction Y may be arranged between two other adjacent gate structures GS. The first buried interconnector 176_1a and the second buried interconnector 176_1b may be arranged in the same direction as a direction in which the gate structure GS extends and may be apart from each other in the first horizontal direction X. A third buried interconnector 176_2a extending in the first horizontal direction X may be arranged between two adjacent first active regions RX1, and a fourth buried interconnector 176_2b extending in the first horizontal direction X may be arranged between the two adjacent first active regions RX1 to be apart from the third buried interconnector 176_2a. The third buried interconnector 176_2a may be electrically connected to the first buried interconnector 176_1a, and the fourth buried interconnector 176_2b may be electrically connected to the second buried interconnector 176_1b.

It is illustrated in FIG. 7 that two buried interconnectors 176 are arranged between the two adjacent first active regions RX1 in the second horizontal direction Y. However, in other some example embodiments, three or more buried interconnectors 176 may be arranged between the two adjacent first active regions RX1 to be apart from one another.

It is illustrated in FIG. 7 that the two buried interconnectors 176 are arranged between the two adjacent first active regions RX1 in the second horizontal direction Y. However, in other some example embodiments, more than two buried interconnectors 176 may be arranged between a first active region RX1 and a second active region RX2 (refer to FIG. 1A) to be apart from each other.

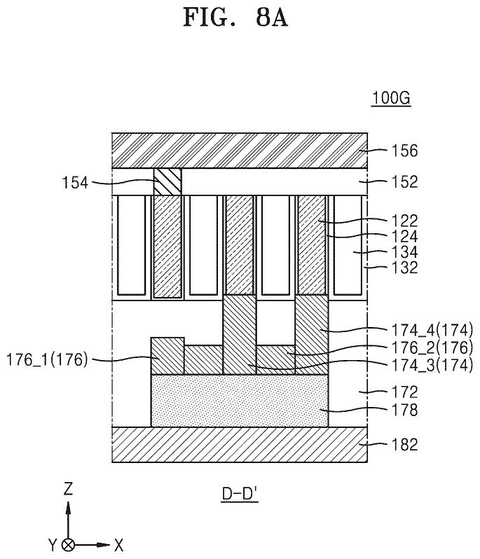

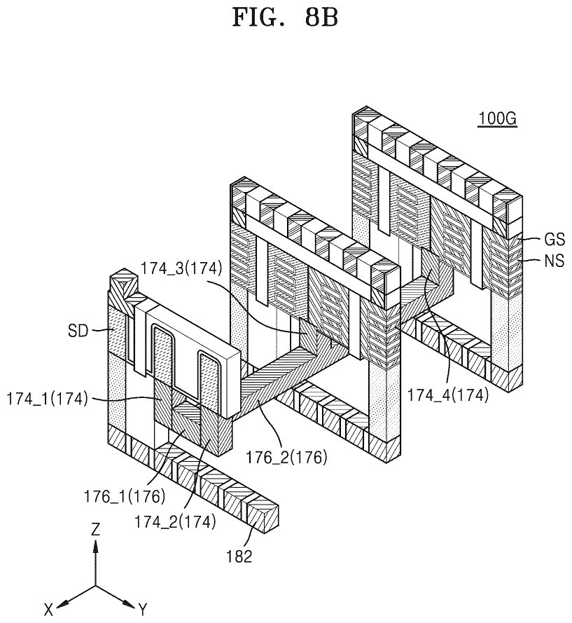

FIG. 8A is a cross-sectional view illustrating an integrated circuit device 100G according to some example embodiments and FIG. 8B is a perspective view illustrating some components of the integrated circuit device 100G.

In FIG. 8B, some components are omitted for convenience of illustration and understanding. For convenience of understanding, in FIG. 8B, two gate structures GS are expressed as being arranged further apart from each other than shown in the cross-sectional view of FIG. 8A, and the source/drain region SD is expressed as being arranged further apart from the gate structure GS than shown in the cross-sectional view of FIG. 8A.

Referring to FIGS. 8A and 8B, a second buried interconnector 1762 may be commonly connected to two gate structures GS. For example, two source/drain regions SD apart from each other in the second horizontal direction Y may be electrically connected to each other by a first rear contact 174_1, a first buried interconnector 176_1, and a second rear contact 174_2. A third rear contact 1743 may be connected to one of the two gate structures GS arranged in the first horizontal direction X, and a fourth rear contact 174_4 may be connected to the other gate structure GS. The second buried interconnector 176_2 extending in the second horizontal direction Y may be connected to the first buried interconnector 176_1, the third rear contact 174_3, and the fourth rear contact 174_4, and may electrically connect the two gate structures GS to the two source/drain regions SD.

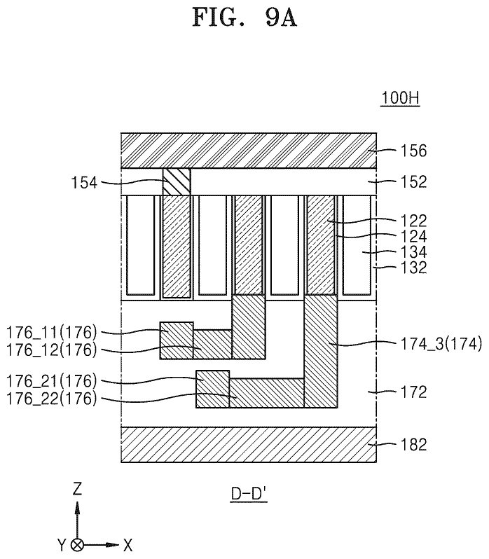

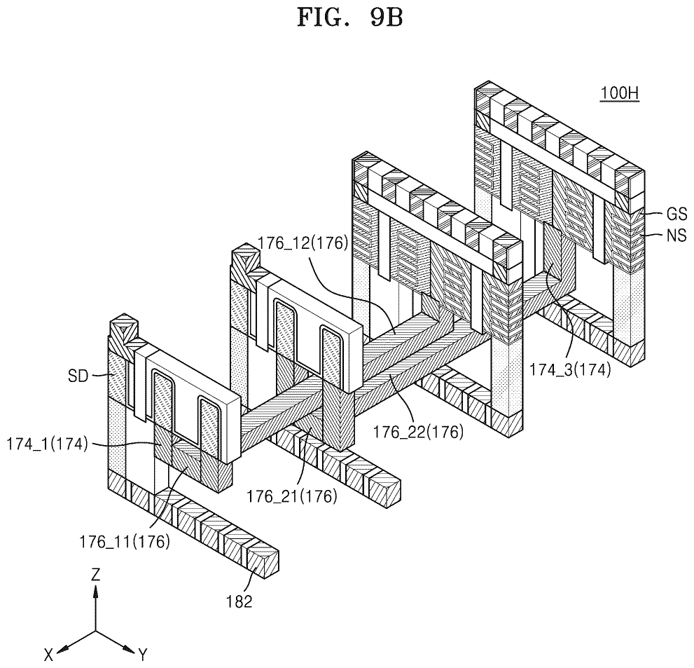

FIG. 9A is a cross-sectional view illustrating an integrated circuit device 100H according to some example embodiments and FIG. 9B is a perspective view illustrating some components of the integrated circuit device 100H.

Referring to FIGS. 9A and 9B, at least part of a buried interconnector 176 may be at a different vertical level from another part of the buried interconnector 176. In some example embodiments, an upper first buried interconnector 176_11 and an upper second buried interconnector 176_12 may be at a first vertical level, a lower first buried interconnector 176_21 and a lower second buried interconnector 17622 may be at a second vertical level lower than the first vertical level, and the second vertical level may indicate a position further away from a bottom surface of a gate structure GS than the first vertical level.

In some example embodiments, as illustrated in FIGS. 9A and 9B, the upper first buried interconnector 176_11 and the upper second buried interconnector 176_12 may not be electrically connected to the lower first buried interconnector 176_21 and the lower second buried interconnector 176_22. However, in other example embodiments, the upper first buried interconnector 176_11 and the upper second buried interconnector 176_12 may be electrically connected to the lower first buried interconnector 176_21 and the lower second buried interconnector 176_22.

In some example embodiments, as illustrated in FIGS. 9A and 9B, the upper second buried interconnector 176_12 may vertically overlap or at least partially overlap with at least one of the lower first buried interconnector 176_21 and the lower second buried interconnector 176_22. However, in other some example embodiments, the upper second buried interconnector 176_12 may not vertically overlap or at least partially overlap with at least one of the lower first buried interconnector 176_21 and the lower second buried interconnector 176_22.

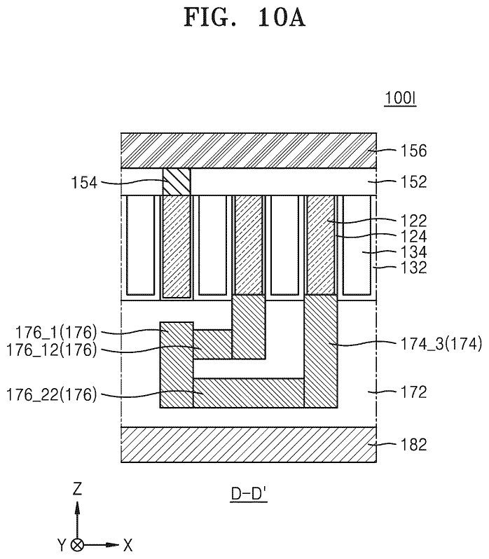

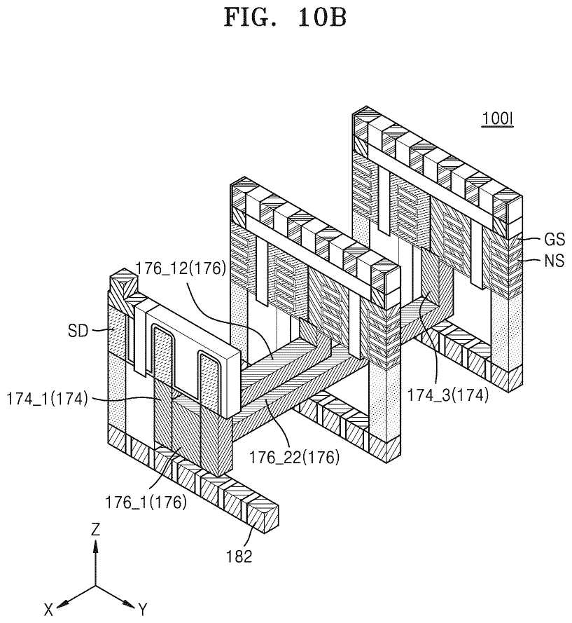

FIG. 10A is a cross-sectional view illustrating an integrated circuit device 100I according to some example embodiments and FIG. 10B is a perspective view illustrating some components of the integrated circuit device 100I.

Referring to FIGS. 10A and 10B, at least part of a buried interconnector 176 may be at a different vertical level from another part of the buried interconnector 176, and the buried interconnectors 176 at different levels may be electrically connected to each other.

In some example embodiments, a first buried interconnector 176_1 may have a relatively large height in the vertical direction Z, and both an upper second buried interconnector 176_12 at a first vertical level and a lower second buried interconnector 176_22 at a second vertical level lower than the first vertical level may be connected to the first buried interconnector 176_1. For example, at least a part of the lower second buried interconnector 176_22 is arranged to vertically overlap or at least partially overlap with the upper second buried interconnector 176_12. However, example embodiments are not limited thereto.

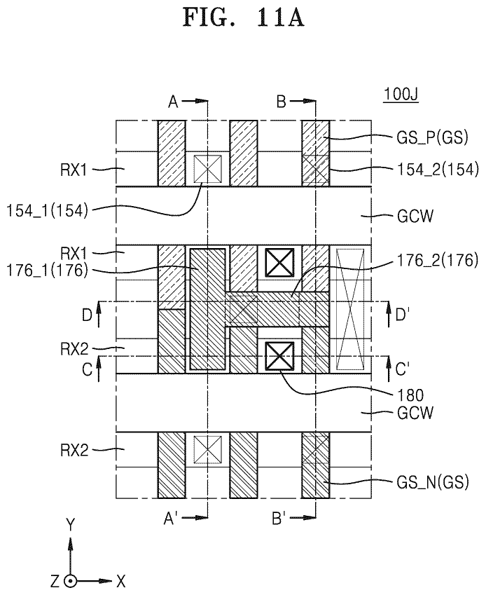

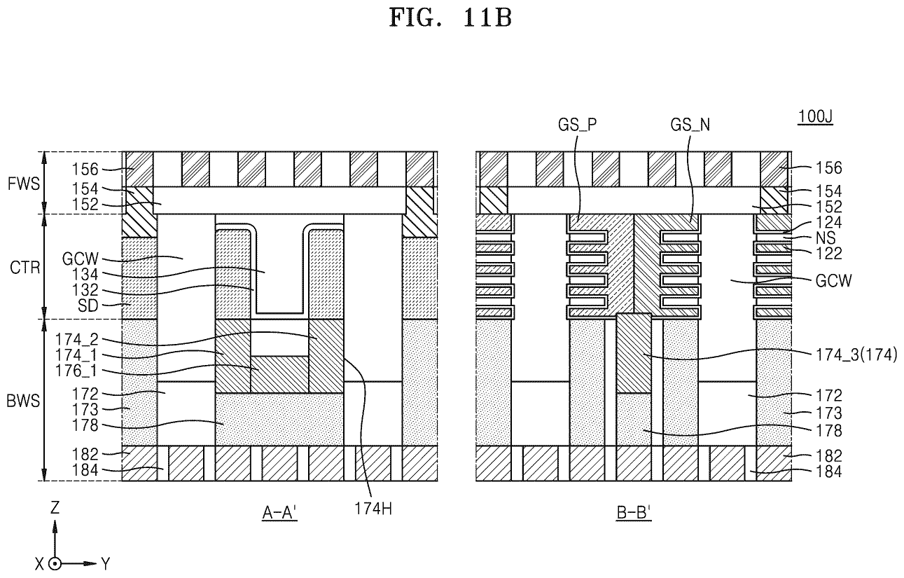

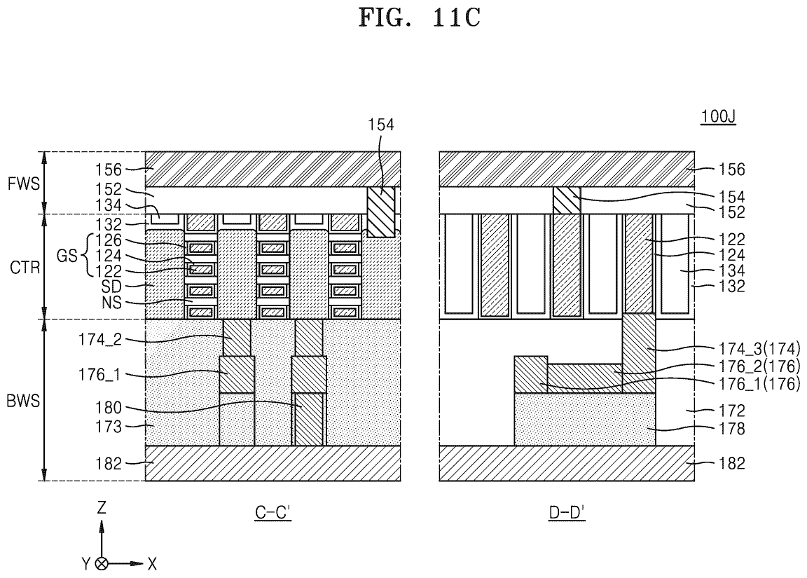

FIG. 11A is a schematic layout diagram illustrating an integrated circuit device 100J according to some example embodiments. FIG. 11B is a cross-sectional view taken along lines A-A′ and B-B′ of FIG. 11A. FIG. 11C is a cross-sectional view taken along lines C-C′ and D-D′ of FIG. 11A.

Referring to FIGS. 11A to 11C, the integrated circuit device 100J may have a forksheet FET structure. In some example embodiments, insulating walls GCW extending in the first horizontal direction X may be arranged between two adjacent first active regions RX1 and two adjacent second active regions RX2. The insulating wall GCW may contact sidewalls of the plurality of semiconductor patterns NS, and the gate insulating layer 124 may extend from a top surface and a bottom surface of each of the plurality of semiconductor patterns NS onto a sidewall of the insulating wall GCW.

It is illustrated in FIG. 11A that one insulating wall GCW is arranged between two adjacent first active regions RX1 and another insulating wall GCW is arranged between two adjacent second active regions RX2. However, in other example embodiments, an insulating wall GCW may be arranged between the first active region RX1 and the second active region RX2.

FIGS. 12A, 12B, 13A, 13B, 14A, 14B, 15A, 15B, 16A, 16B, 17A, 17B, 18A, 18B, 19A, 19B, 20A, 20B, 21A, 21B, 22A, 22B, 23A, 23B, 24A, 24B, 25A, 25B, 26A, 26B, 27A, 27B, 28A, 28B, 29A, 29B, 30A, and 30B are cross-sectional views illustrating a method of manufacturing an integrated circuit device 100 according to some example embodiments.

Referring to FIGS. 12A and 12B, a sacrificial layer 210L and a semiconductor layer NSL may be alternately and sequentially formed on a top surface of a substrate 110 to form a semiconductor layer stack NSS. The sacrificial layer 210L and the semiconductor layer NSL may be formed by an epitaxy process.

In some example embodiments, the sacrificial layer 210L and the semiconductor layer NSL may include a material having etch selectivity with respect to each other. For example, the sacrificial layer 210L and the semiconductor layer NSL may each include a single crystal layer of a group IV semiconductor, a group IV-IV compound semiconductor, or a group III-V compound semiconductor and may include different materials. In an example, the sacrificial layer 210L may include SiGe, and the semiconductor layer NSL may include single crystal silicon.

In some example embodiments, the epitaxy process may include a chemical vapor deposition (CVD) process such as vapor-phase epitaxy (VPE) or ultra-high vacuum chemical vapor deposition (UHV-CVD), molecular beam epitaxy, or a combination thereof. In the epitaxy process, a liquid or gaseous precursor may be used as a precursor to form the sacrificial layer 210L and the semiconductor layer NSL.

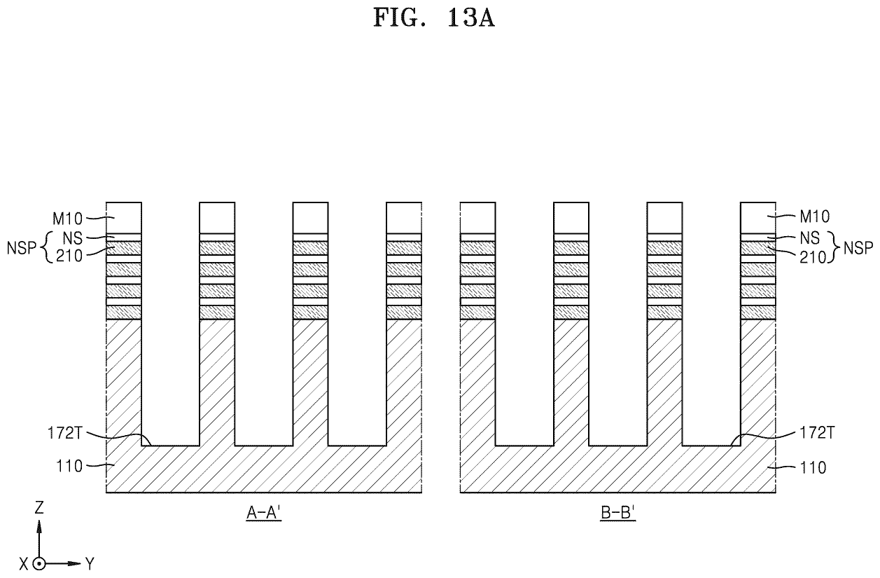

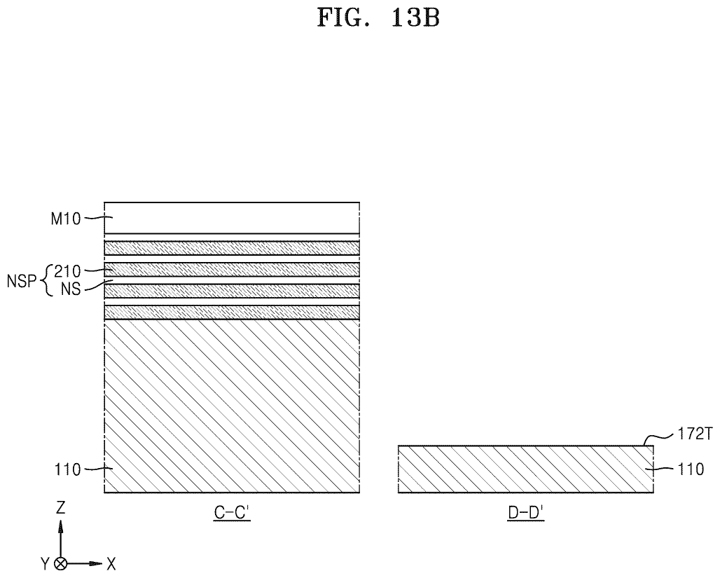

Referring to FIGS. 13A and 13B, after a hard mask pattern M10 is formed on the semiconductor layer stack NSS, the sacrificial layer 210L, the semiconductor layer NSL, and the substrate 110 may be etched by using the hard mask pattern M10 as an etch mask to form a semiconductor layer pattern NSP and a device isolation trench 172T.

In some example embodiments, the hard mask pattern M10 may extend in the first horizontal direction X. As the hard mask pattern M10 extends in the first horizontal direction X, the semiconductor layer pattern NSP and the device isolation trench 172T may also extend in the first horizontal direction X.

In some example embodiments, the semiconductor layer pattern NSP may include a plurality of semiconductor patterns NS and a plurality of sacrificial layer patterns 210 alternately stacked on the top surface of the substrate 110.

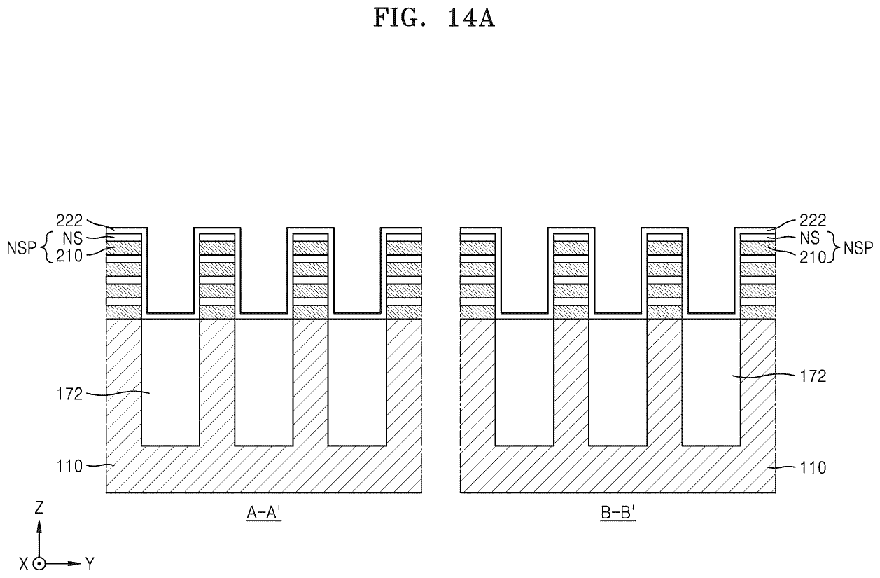

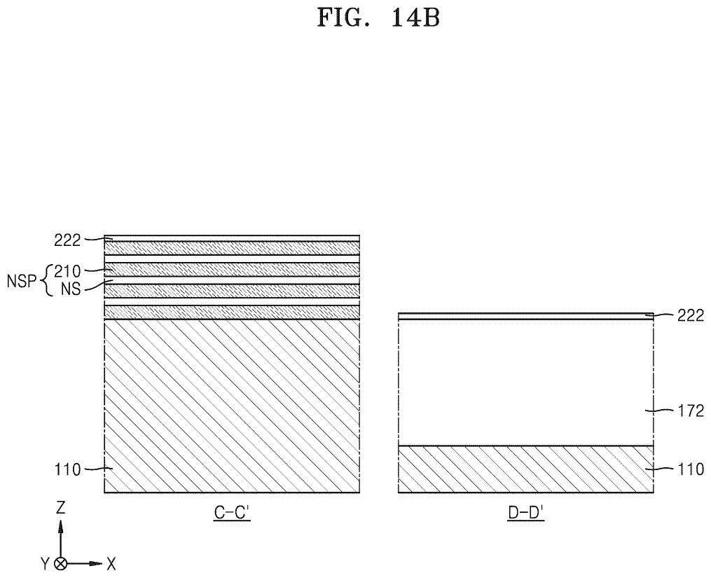

Referring to FIGS. 14A and 14B, the first device isolation layer 172 may be formed on an internal wall of the device isolation trench 172T. The first device isolation layer 172 may include silicon oxide. Thereafter, a dummy gate insulating layer 222 may be formed on the first device isolation layer 172 and the top surface of the substrate 110 to cover the semiconductor layer pattern NSP. The dummy gate insulating layer 222 may include silicon oxide.

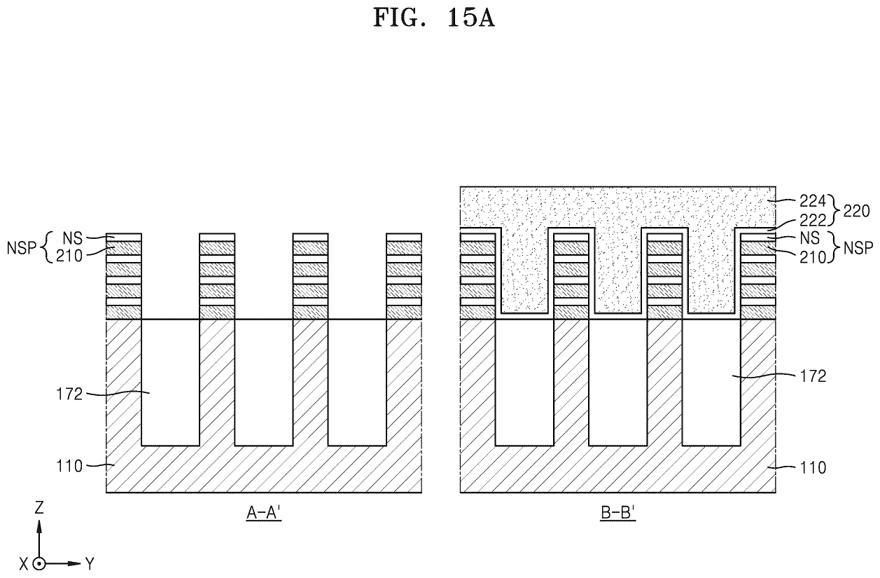

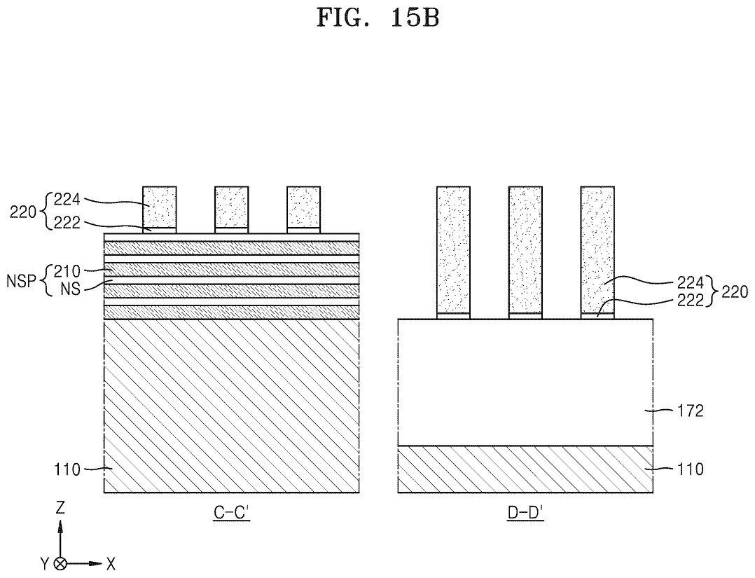

Referring to FIGS. 15A and 15B, a dummy gate electrode 224 extending in the second horizontal direction Y may be formed on the dummy gate insulating layer 222. In a process of patterning the dummy gate electrode 224, part of the dummy gate insulating layer 222 may also be removed, and part of the top surface of the substrate 110 covered with the dummy gate insulating layer 222 may be exposed again.

In some example embodiments, the dummy gate electrode 224 may include polysilicon.

Here, the dummy gate electrode 224 and the dummy gate insulating layer 222 are referred to as a dummy gate structure 220.

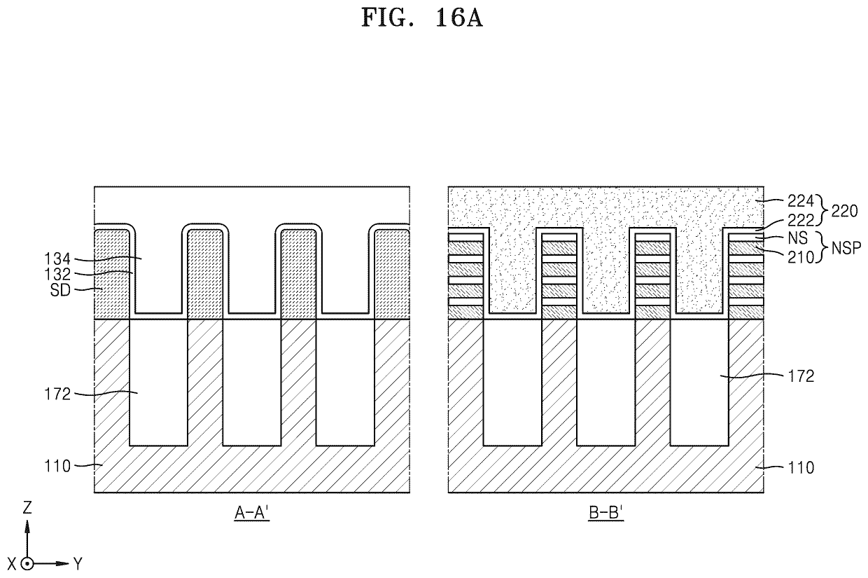

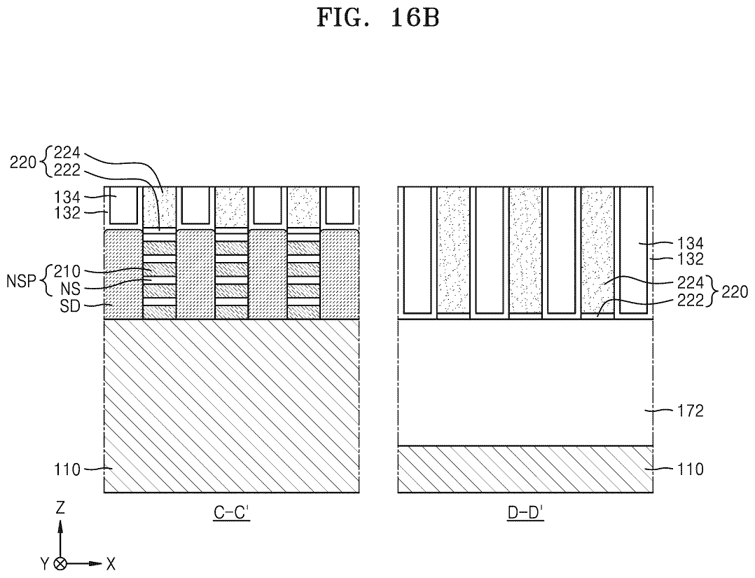

Referring to FIGS. 16A and 16B, the semiconductor layer patterns NSP on both sides of the dummy gate structure 220 may be etched to expose the top surface of the substrate 110. Thereafter, the source/drain region SD may be formed on the top surface of the substrate 110 exposed on both sides of the dummy gate structure 220.

In some example embodiments, the source/drain region SD may be formed by epitaxially growing a semiconductor material from the plurality of semiconductor patterns NS, the plurality of sacrificial layer patterns 210, and a surface of the substrate 110. The source/drain region SD may include at least one of an epitaxially grown Si layer, an epitaxially grown SiC layer, an epitaxially grown SiGe layer, and an epitaxially grown SiP layer.

Thereafter, the insulating liner 132 and the inter-gate insulating layer 134 covering the source/drain region SD may be formed.

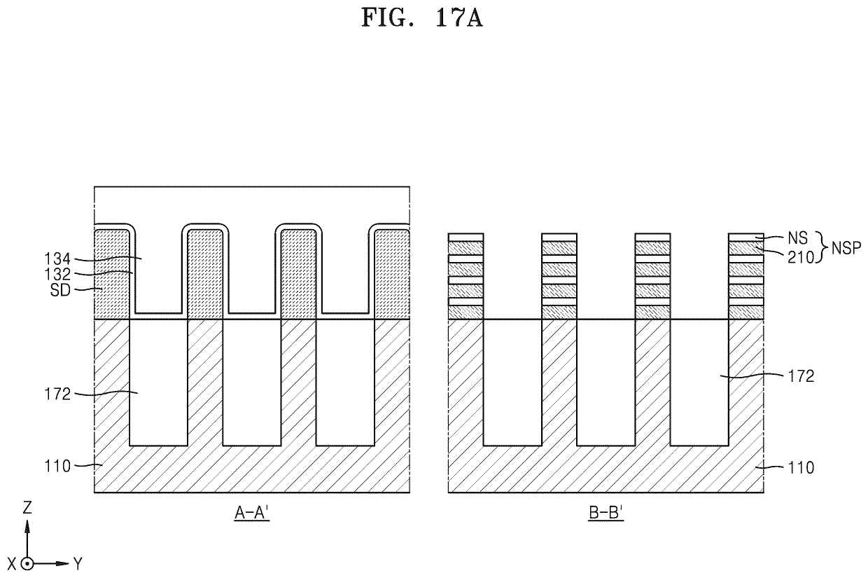

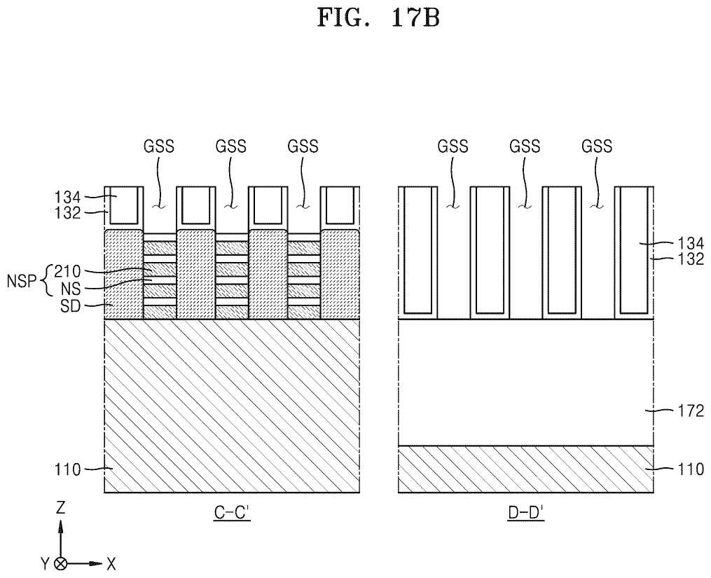

Referring to FIGS. 17A and 17B, the dummy gate structure 220 may be removed to form (for example, define) a gate space GSS. The gate space GSS may refer to a space defined or at least partially defined between the inter-gate insulating layers 134 arranged at a position from which the dummy gate structure 220 is removed. A top surface and sidewalls of the semiconductor layer pattern NSP may be exposed to the gate space GSS.

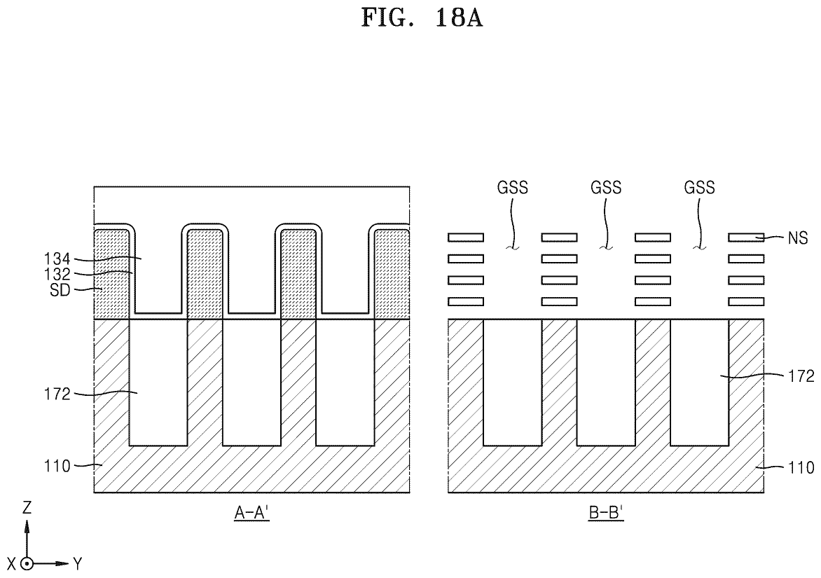

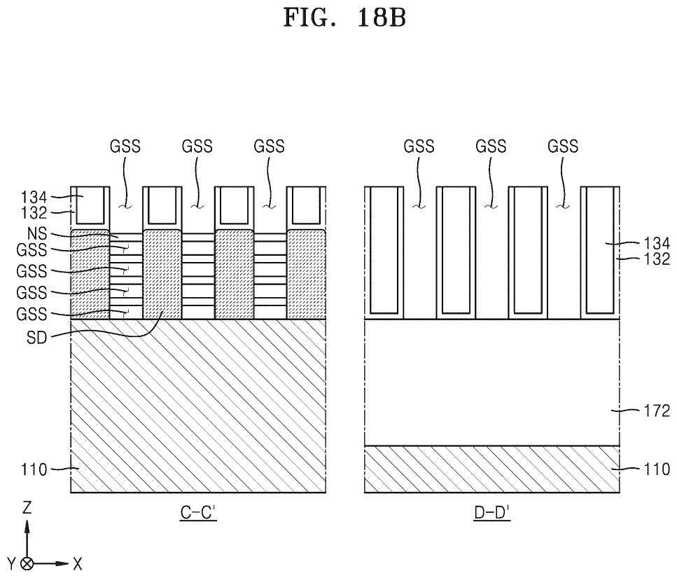

Referring to FIGS. 18A and 18B, the plurality of sacrificial layer patterns 210 may be removed through the gate space GSS to partially expose the plurality of semiconductor patterns NS and the top surface of the substrate 110. The gate spaces GSS may extend between each two of the plurality of semiconductor patterns NS and between the lowermost semiconductor pattern NS and the substrate 110. The process of removing the plurality of sacrificial layer patterns 210 may be, for example, a wet etching process using a etch selectivity between the plurality of sacrificial layer patterns 210 and the plurality of semiconductor patterns NS, but example embodiments are not limited thereto.

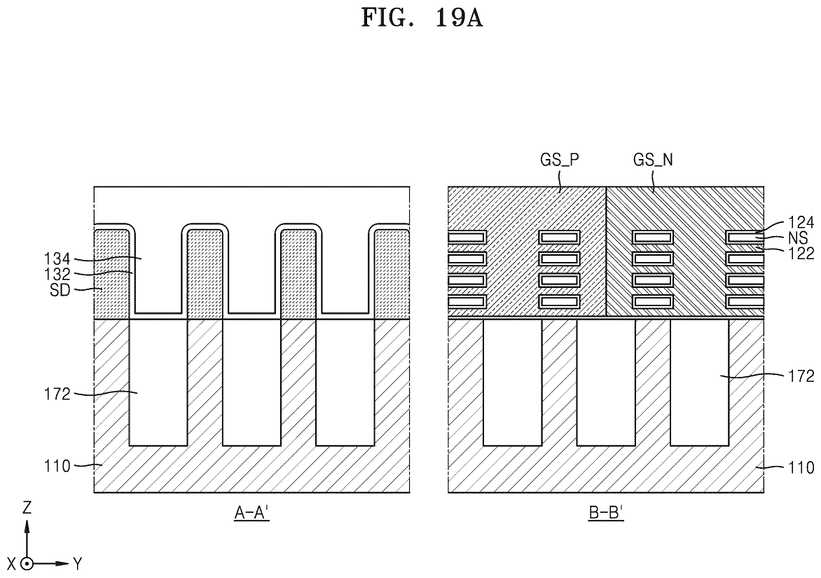

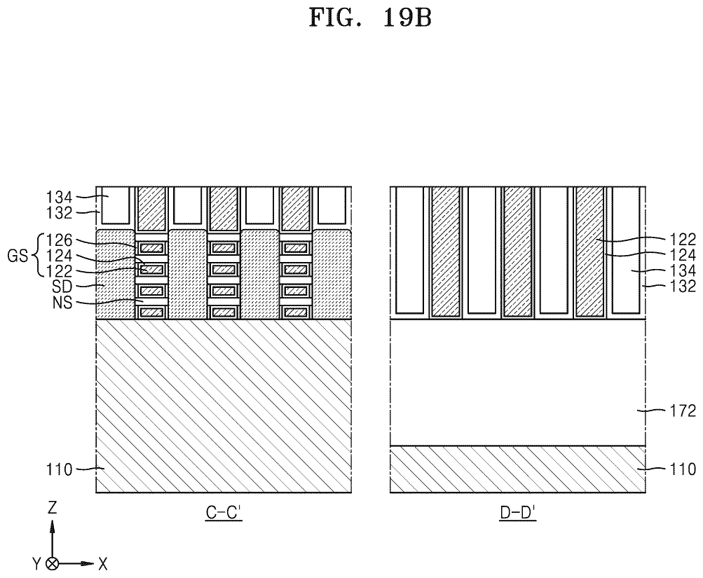

Referring to FIGS. 19A and 19B, the gate spacer 126 may be formed on sidewalls of the source/drain region SD exposed to the gate space GSS, and the gate insulating layer 124 may be formed on surfaces exposed to the gate space GSS. Thereafter, the gate electrode 122 filling the gate space GSS may be formed on the gate insulating layer 124.

For example, after a work function conductive layer (not shown) is conformally formed on an internal wall of the gate space GSS, a buried conductive layer (not shown) may be formed on the work function conductive layer to fill the gate space GSS. Thereafter, an upper portion of the buried conductive layer may be planarized until a top surface of the inter-gate insulating layer 134 is exposed to form the gate electrode 122.

In some example embodiments, the work function control layer may include Al, Cu, Ti, Ta, W, Mo, TaN, NiSi, CoSi, TiN, WN, TiAl, TiAlC, TiAlN, TaCN, TaC, TaSiN, or a combination thereof. The buried conductive layer may include Al, Cu, Ti, Ta, W, Mo, TaN, NiSi, CoSi, TiN, WN, TiAl, TiAlC, TiAlN, TaCN, TaC, TaSiN, or a combination thereof.

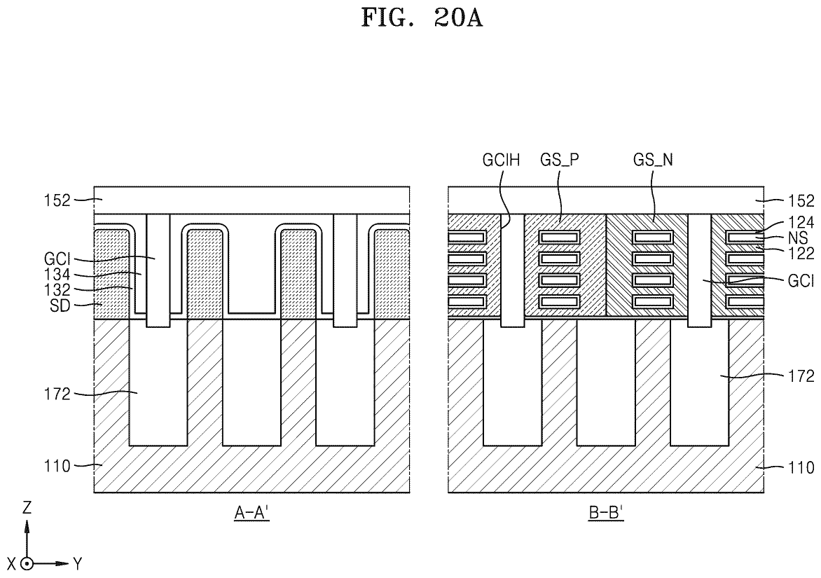

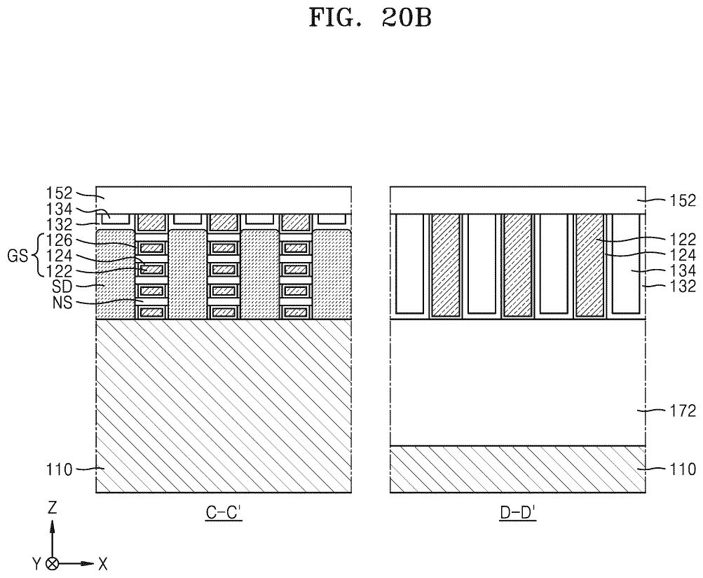

Referring to FIGS. 20A and 20B, a partial region of the gate structure GS may be removed to form a gate cut region GCIH, and a gate cut insulating layer GCI may be formed in the gate cut region GCIH.

In some example embodiments, the gate cut region GCIH may be formed by removing a partial region of the gate structure GS and a partial region of the inter-gate insulating layer 134, and in this case, the gate cut insulating layer GCI may be formed in a line shape extending in the first horizontal direction X, and part of the gate cut insulating layer GCI may be arranged between two adjacent source/drain regions SD. In other example embodiments, the gate cut region GCIH may be formed by removing only a partial region of the gate structure GS, and in this case, both sidewalls of the gate cut insulating layer GCI may be aligned with both sidewalls of the gate structure GS, and the gate cut insulating layer GCI may not be arranged between two adjacent source/drain regions SD.

Thereafter, the upper insulating layer 152 is formed on the gate electrode 122 and the inter-gate insulating layer 134.

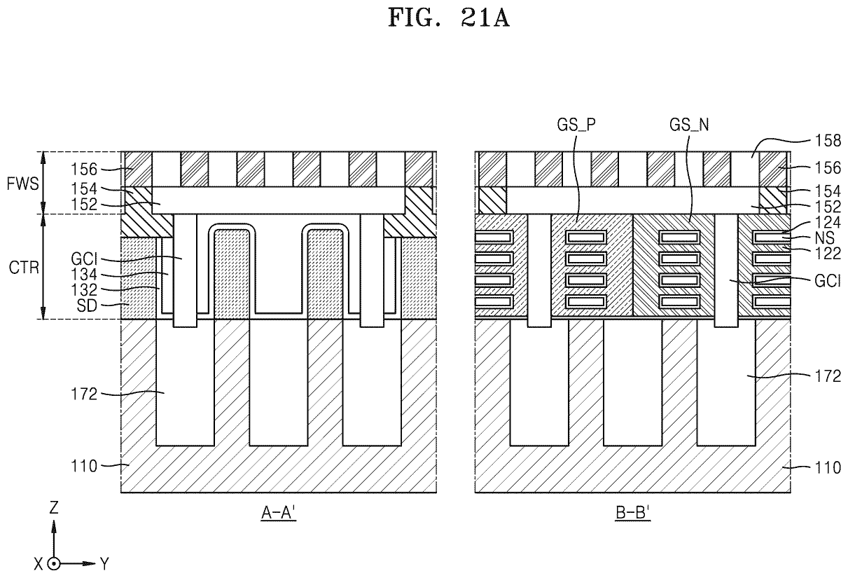

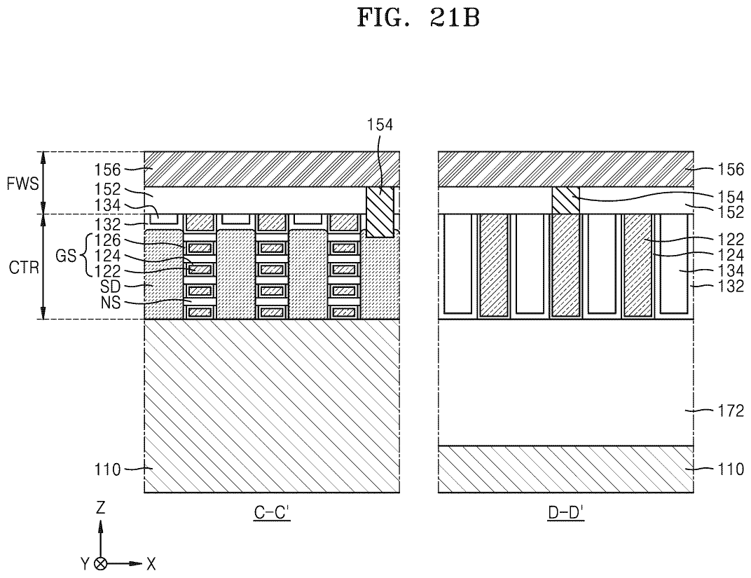

Referring to FIGS. 21A and 21B, the front contact 154 electrically connected to the source/drain region SD or the gate electrode 122 may be formed through the upper insulating layer 152. For example, the front wiring layer 156 and the front insulating layer 158 may be formed on the front contact 154 and the upper insulating layer 152. Accordingly, a front wiring structure FWS may be completed.

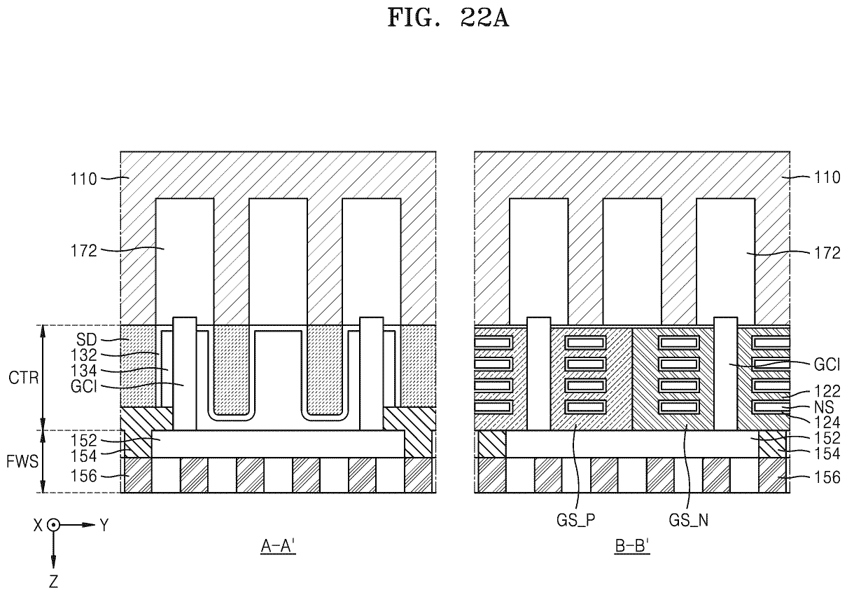

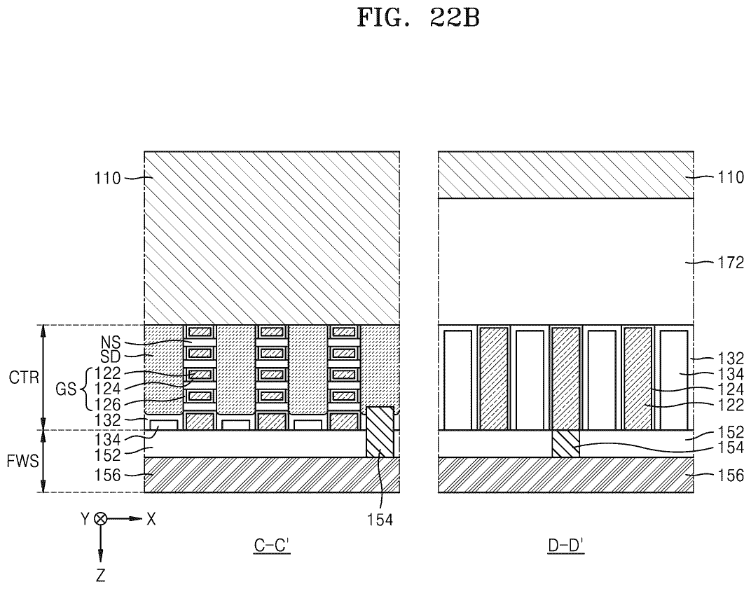

Referring to FIGS. 22A and 22B, a carrier substrate may be attached to the front wiring structure FWS, and the substrate 110 may be turned over so that a bottom surface of the substrate 110 faces upward.

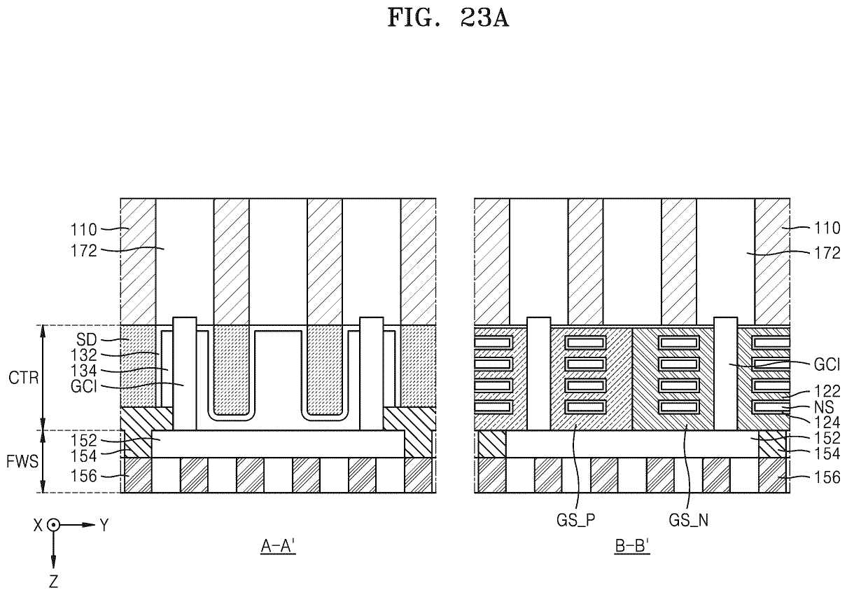

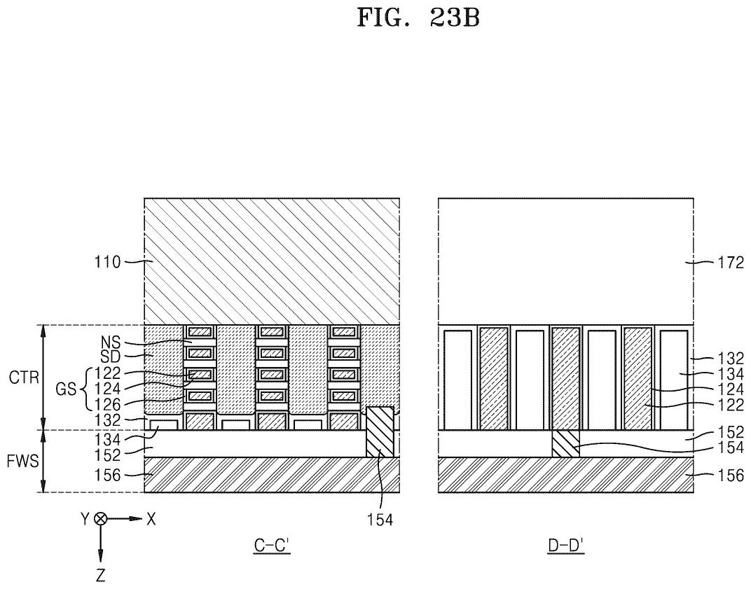

Referring to FIGS. 23A and 23B, part of the substrate 110 may be removed to reduce a height of the substrate 110 in the vertical direction Z. In some example embodiments, a grinding process may be performed until a top surface of the first device isolation layer 172 is exposed.

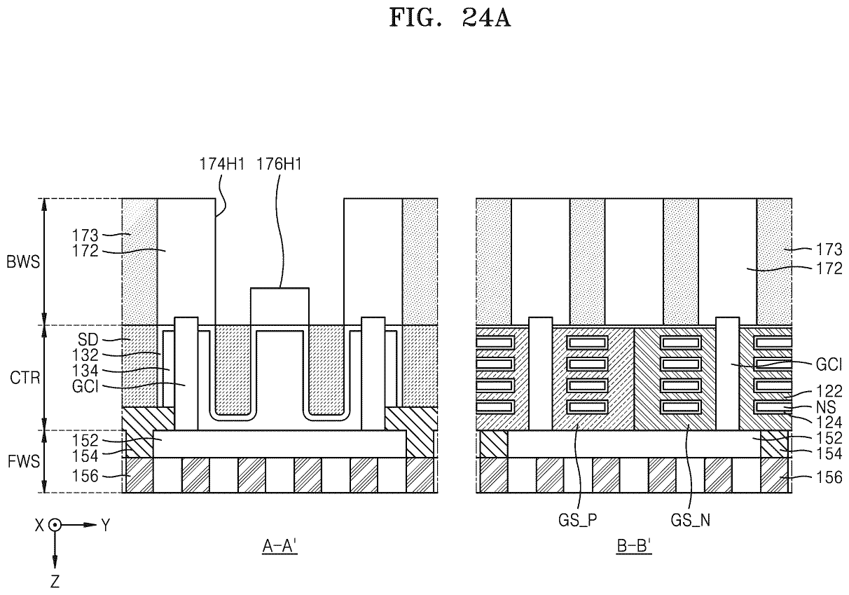

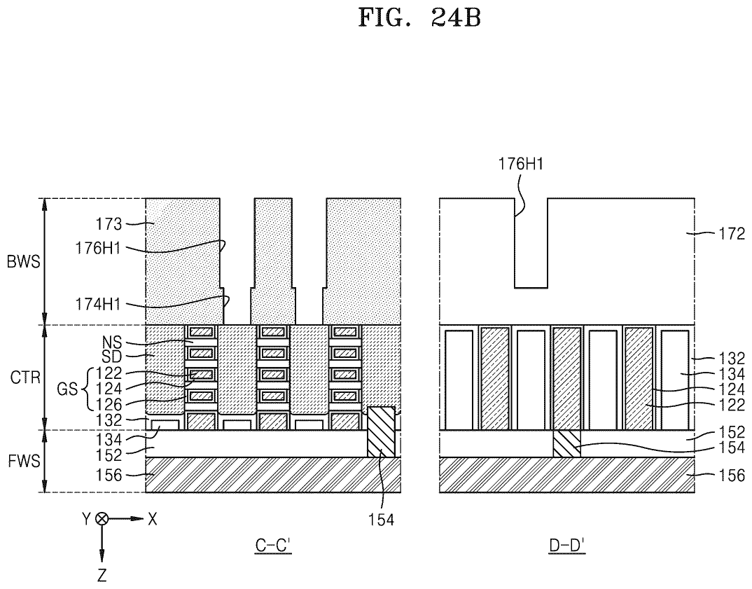

Referring to FIGS. 24A and 24B, the substrate 110 may be removed. Thereafter, the second device isolation layer 173 may be formed by filling a position from which the substrate 110 is removed with an insulating material.

In some example embodiments, a process for removing the substrate 110 may include a wet etching process or a recess process. The first device isolation layer 172 may remain without being removed in the wet etching process or the recess process.

In some example embodiments, the second device isolation layer 173 may include an oxide layer, a nitride layer, a low-k dielectric layer having a dielectric constant of about 2.2 to about 2.4, or a combination thereof.

Thereafter, a mask pattern may be formed on a top surface of the second device isolation layer 173, and part of the second device isolation layer 173 may be removed to form (for example, define) the first rear contact hole 174H1. The first rear contact hole 174H1 may expose the top surface of the source/drain region SD through the second device isolation layer 173.

In some example embodiments, a part of the first device isolation layer 172 may be removed to form the first recess region 176H1 connected to (for example, in communication with) the first rear contact hole 174H1. The first recess region 176H1 may be formed (for example, defined) by removing a part of the first device isolation layer 172 to a depth that does not completely pass through the first device isolation layer 172.

In some example embodiments, the process of forming (for example, defining) the first recess region 176H1 may be performed after the process of forming the first rear contact hole 174H1. For example, the first rear contact hole 174H1 may be formed (for example, defined) by removing a part of the second device isolation layer 173 by using a first mask pattern, and then a part of the first device isolation layer 172 may be removed at a position adjacent to the first rear contact hole 174H1 by using a second mask pattern to form the first recess region 176H1 at a position connected to the first rear contact hole 174H1.

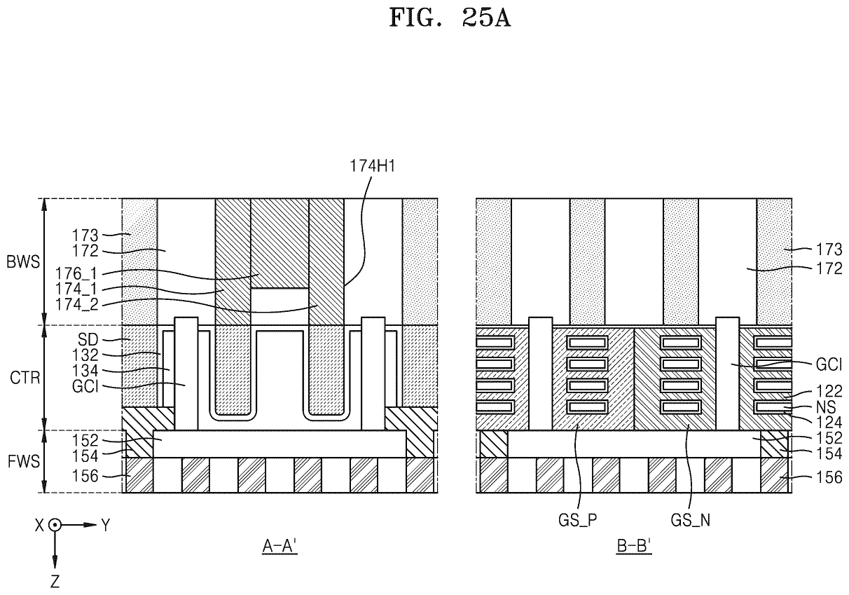

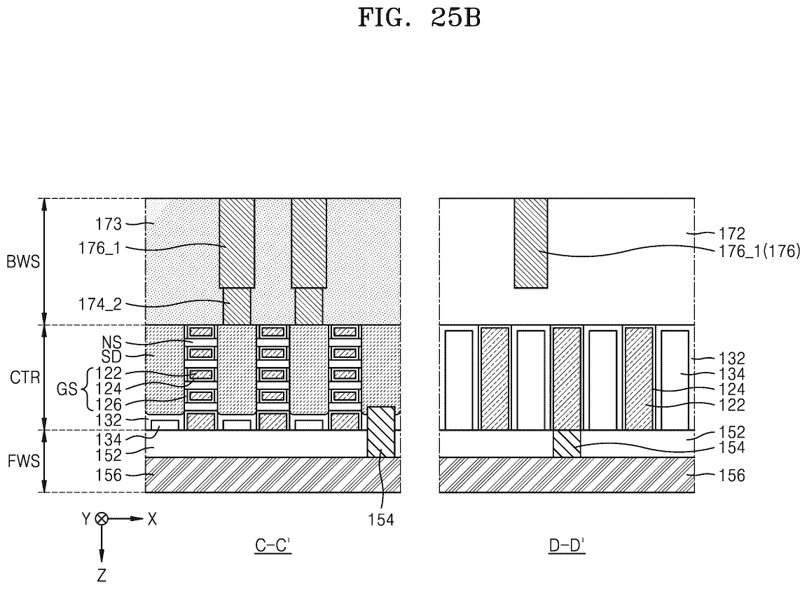

Referring to FIGS. 25A and 25B, the first rear contact 174_1 and the second rear contact 174_2 may be formed by, for example, using a conductive material in the first rear contact hole 174H1, and the first buried interconnector 1761 may be formed by using a conductive material in the first recess region 176H1.

In some example embodiments, the first rear contact 1741 may be arranged on the top surface of one source/drain region SD, the second rear contact 1742 may be arranged on the top surface of the other source/drain region SD, and the first buried interconnector 1761 may be arranged between the first rear contact 174_1 and the second rear contact 174_2.

In some example embodiments, the first rear contact 174_1, the second rear contact 174_2, and the first buried interconnector 176_1 may include W, Co, Mo, Ni, Ru, Cu, Al, a silicide thereof, and/or any alloy thereof.

Although boundaries among the first rear contact 174_1, the second rear contact 174_2, and the first buried interconnector 176_1 are illustrated in FIGS. 25A and 25B for convenience of understanding, the first rear contact 174_1, the second rear contact 174_2, and the first buried interconnector 176_1 may be, for example, integrally formed to be connected to one another, and the boundaries therebetween may not be discernible, but example embodiments are not limited thereto.

In some example embodiments, a metal silicide layer may be further formed on the top surface of the source/drain region SD exposed to a bottom surface of the first rear contact hole 174H1 before forming the first rear contact 174_1, the second rear contact 174_2, and the first buried interconnector 176_1.

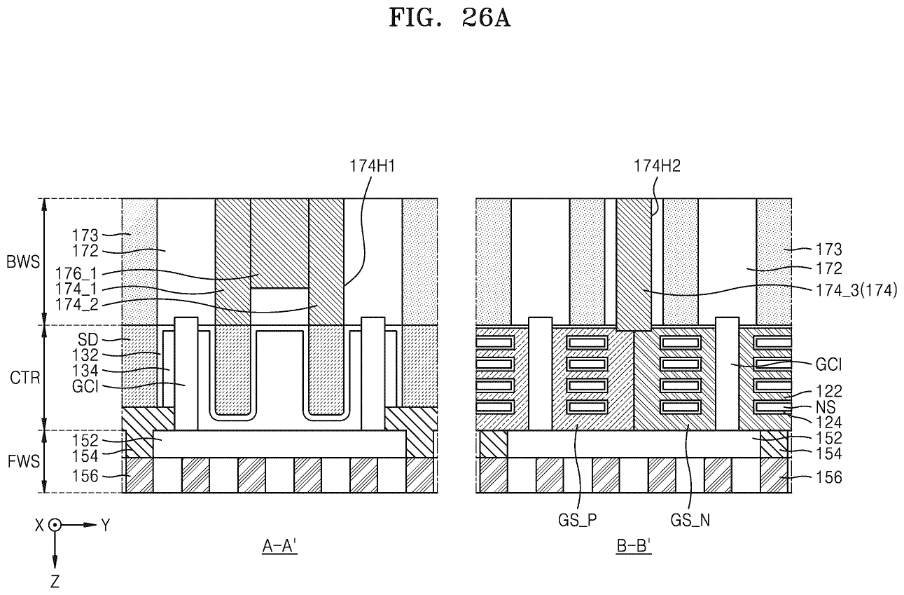

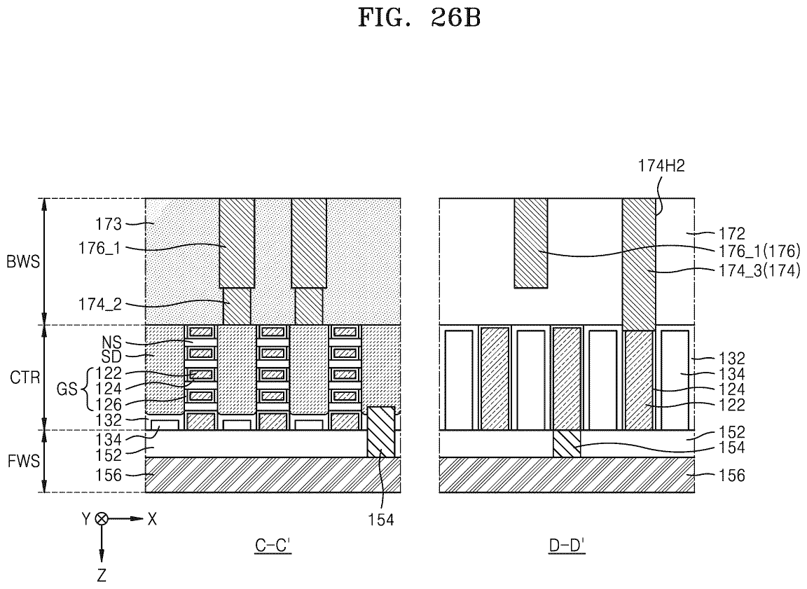

Referring to FIGS. 26A and 26B, a mask pattern may be formed on the top surface of the first device isolation layer 172 and part of the first device isolation layer 172 may be removed to form the second rear contact hole 174H2. The second rear contact hole 174H2 may expose a top surface of the gate electrode 122 through the first device isolation layer 172.

Thereafter, a third rear contact 174_3 may be formed by using a conductive material in the second rear contact hole 174H2.

In some example embodiments, the third rear contact 1743 may include at least one of W, Co, Mo, Ni, Ru, Cu, Al, silicide thereof, and an alloy thereof.

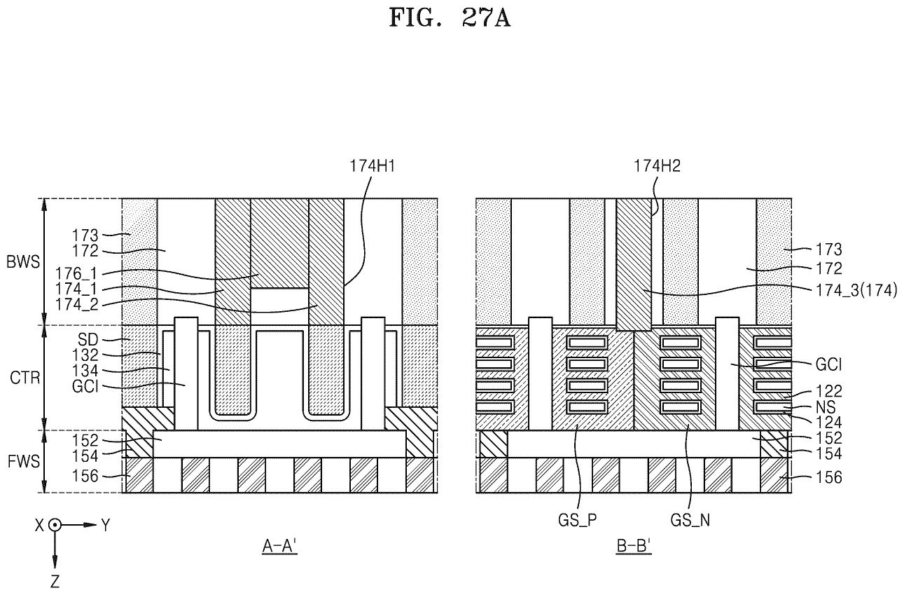

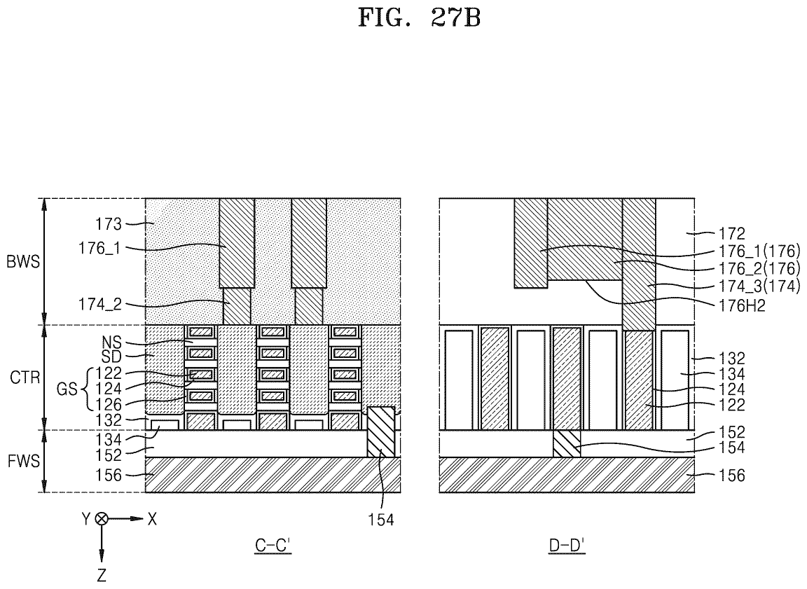

Referring to FIGS. 27A and 27B, a mask pattern may be formed on the top surface of the first device isolation layer 172 and part of the first device isolation layer 172 may be removed to form the second recess region 176H2. The second recess region 176H2 may be formed by removing part of the first device isolation layer 172 to a depth that does not completely pass through the first device isolation layer 172.

In a plan view, the second recess region 176H2 may be formed between the first buried interconnector 176_1 and the third rear contact 174_3, and a sidewall of the third rear contact 174_3 and a sidewall of the first buried interconnector 1761 may be exposed in the second recess region 176H2.

Thereafter, the second buried interconnector 1762 may be formed by using a conductive material in the second recess region 176H2.

In some example embodiments, the first to third rear contacts 174_1, 174_2, and 174_3 and the first and second buried interconnectors 176_1 and 176_2 may have top surfaces arranged on the same plane, and the top surfaces of the first to third rear contacts 174_1, 174_2, and 174_3 and the first and second buried interconnectors 176_1 and 176_2 may be arranged on the same plane as the top surfaces of the first and second device isolation layers 172 and 173.

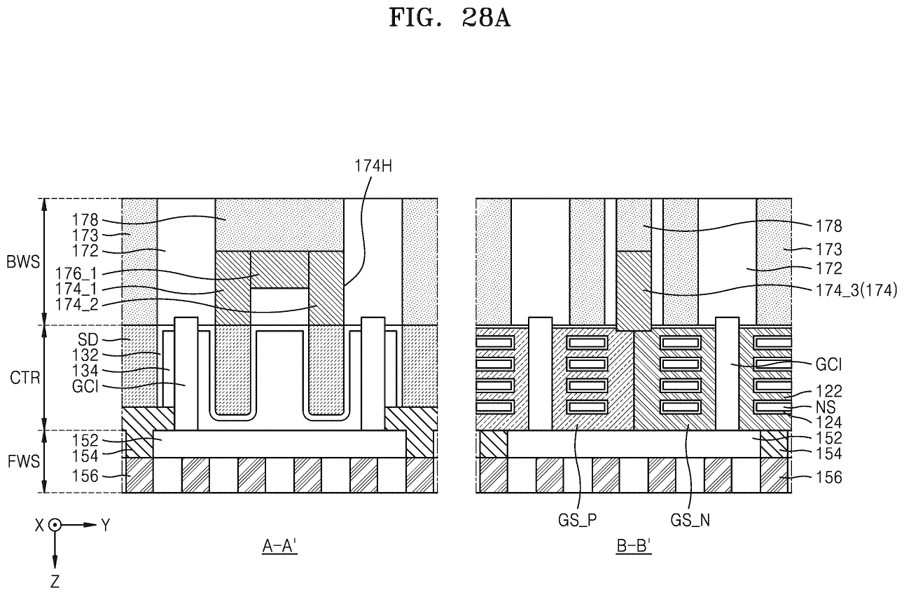

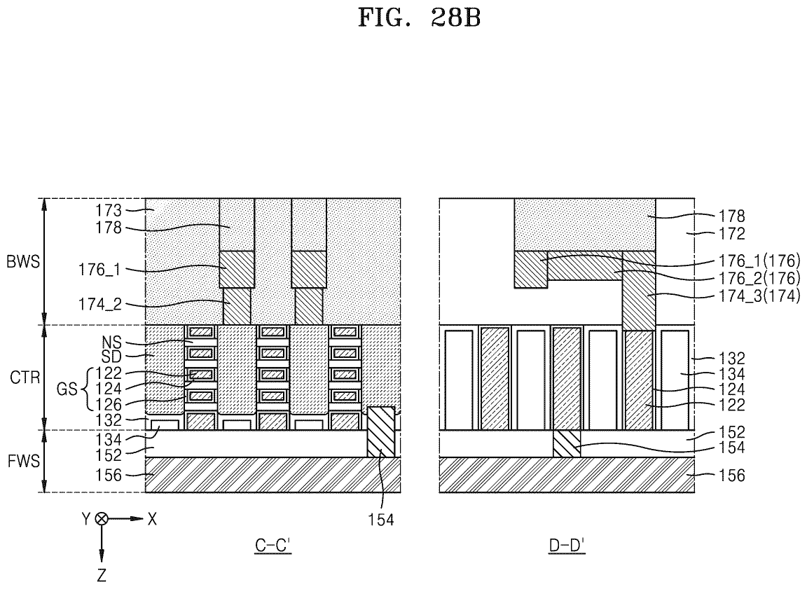

Referring to FIGS. 28A and 28B, a recess process may be performed on the top surfaces of the first to third rear contacts 174_1, 174_2, and 174_3 and the first and second buried interconnectors 176_1 and 176_2 to lower a level of the top surfaces of the first to third rear contacts 174_1, 174_2, and 174_3 and the first and second buried interconnectors 176_1 and 176_2.

In some example embodiments, the recess process may include, for example, a wet etching process or an etch-back process, but example embodiments are not limited thereto. In the recess process, the first and second device isolation layers 172 and 173 may be hardly etched or removed, and only upper portions of the first to third rear contacts 174_1, 174_2, and 174_3 and the first and second buried interconnectors 176_1 and 176_2 may be removed.

As a result of performing the recess process, the top surfaces of the first to third rear contacts 174_1, 174_2, and 174_3 and the first and second buried interconnectors 176_1 and 176_2 may be at a lower vertical level than the top surfaces of the first and second device isolation layers 172 and 173.

Thereafter, the buried insulating layer 178 may be formed on the top surfaces of the first to third rear contacts 174_1, 174_2, and 174_3 and the first and second buried interconnectors 176_1 and 1762 by using an insulating material.

In some example embodiments, the buried insulating layer 178 may include an oxide layer, a nitride layer, a low-k dielectric layer, or a combination thereof. In some example embodiments, the buried insulating layer 178 may include a low dielectric constant insulating layer including at least one of carbon-containing silicon oxide, carbon-containing silicon oxynitride, carbon-containing silicon nitride, or silicon carbon boron nitride.

Here, the first to third rear contacts 174_1, 174_2, and 174_3 are referred to as the rear contact 174, and the first and second buried interconnectors 176_1 and 176_2 are referred to as the buried interconnector 176. It will be understood that the number and arrangements of rear contacts 174 and buried interconnectors 176 may vary, reflecting various cell layouts according to a design of an integrated circuit device.

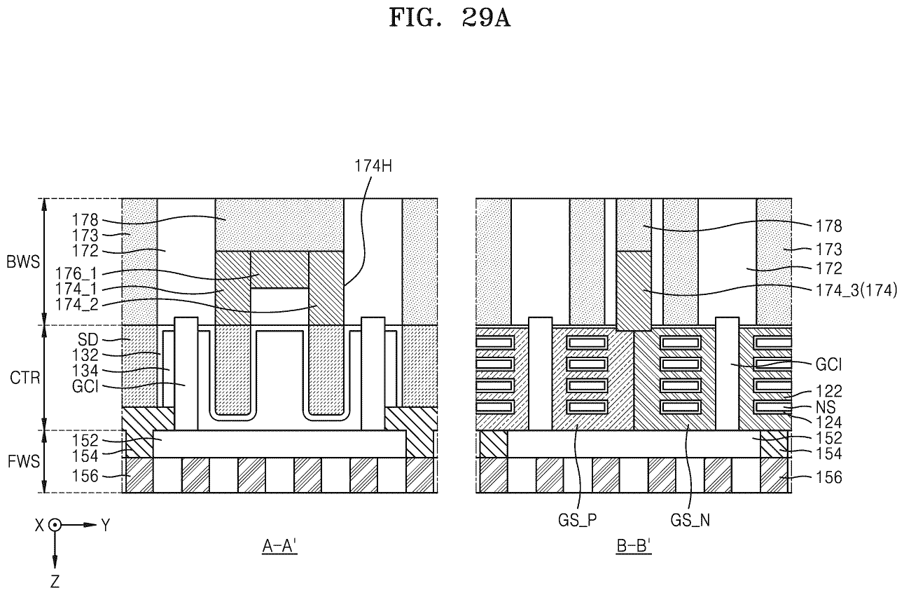

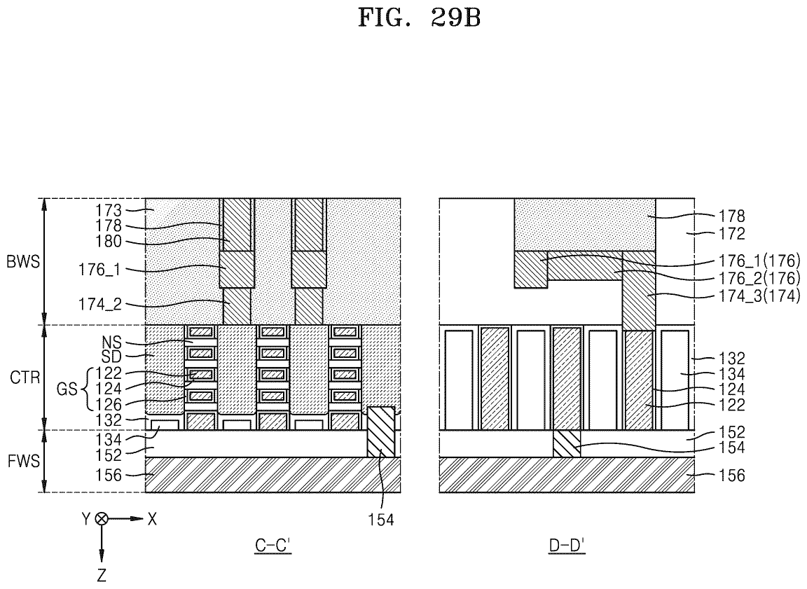

Referring to FIGS. 29A and 29B, the rear via 180 connected to the rear contact 174 or the buried interconnector 176 may be formed through the buried insulating layer 178. For example, the rear via 180 may be formed on the top surface of the first buried interconnector 176_1.

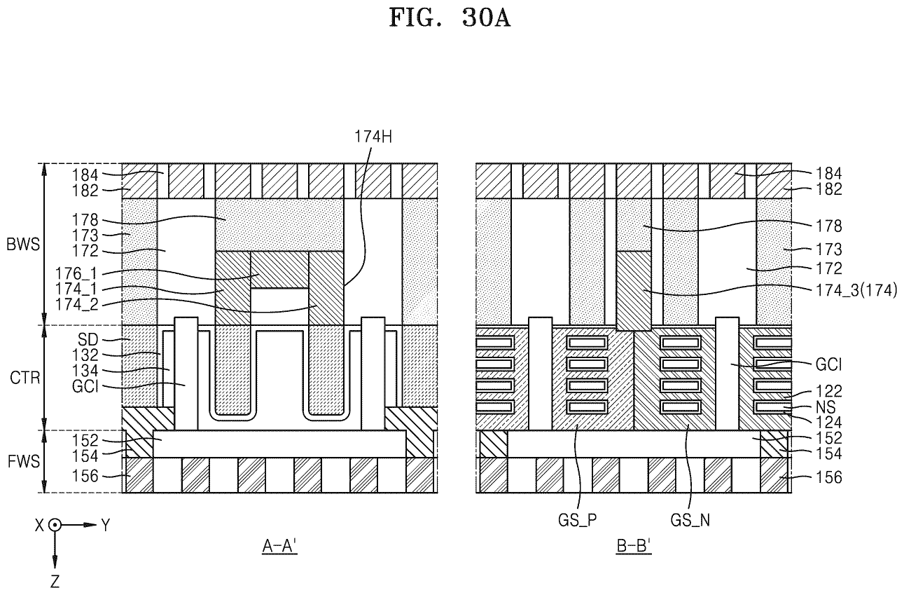

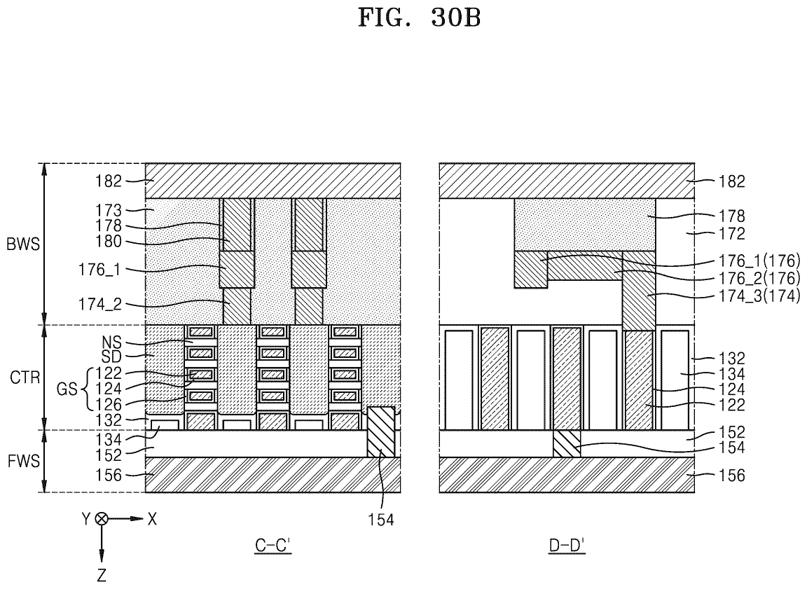

Referring to FIGS. 30A and 30B, the rear wiring layer 182 and the rear insulating layer 184 may be formed on the first and second device isolation layers 172 and 173 and the buried insulating layer 178.

The integrated circuit device 100 may be formed by the above-described process. In a manufacturing process according to some example embodiments, a buried interconnector may be formed by using a recess process to provide electrical connection between at least two rear contacts. Accordingly, although a device isolation layer is formed to a relatively large thickness, shortened wiring routing may be implemented through the buried interconnector, and a freedom of routing of a front wiring structure may be improved. Accordingly, the integrated circuit device may have relatively high electrical performance.

While inventive concepts have been particularly shown and described with reference to example embodiments thereof, it will be understood by one of ordinary skill in the art that various changes in form and details may be made therein without departing from the spirit and scope of the following claims.

Terms, such as first, second, etc. may be used herein to describe various elements, but these elements should not be limited by these terms. The above terms are used only for the purpose of distinguishing one component from another. For example, a first element may be termed a second element, and, similarly, a second element may be termed a first element, without departing from the scope of the present disclosure.

Singular expressions may include plural expressions unless the context clearly indicates otherwise. Terms, such as “include” or “has” may be interpreted as adding features, numbers, steps, operations, components, parts, or combinations thereof described in the specification.

It will be understood that when an element or layer is referred to as being “on”, “connected to”, “coupled to”, “attached to”, or “in contact with” another element or layer, it can be directly on, connected to, coupled to, attached to, or in contact with the other element or layer, or intervening elements or layers may be present. In contrast, when an element is referred to as being “directly on”, “directly connected to”, “directly coupled to”, “directly attached to”, or “in direct contact with” another element or layer, there are no intervening elements or layers present. As used herein, the term “and/or” includes any and all combinations of one or more of the associated listed items.

Spatially relative terms (e.g., “beneath,” “below,” “lower,” “above,” “upper,” and the like) may be used herein for ease of description to describe one element or feature's relationship to another element(s) or feature(s) as illustrated in the figures. It should be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented (rotated 90 degrees or at other at other orientations) and the spatially relative descriptors used herein interpreted accordingly.

What is claimed is:

1. An integrated circuit device, comprising:
a plurality of cell transistors at a first vertical level;
a front wiring structure at a second vertical level and electrically connected to the plurality of cell transistors, the second vertical level higher than the first vertical level; and
a rear wiring structure at a third vertical level and electrically connected to the plurality of cell transistors, the third vertical level lower than the first vertical level, wherein the rear wiring structure comprises
a device isolation layer on bottom surfaces of the plurality of cell transistors;
a plurality of rear contacts electrically connected to the plurality of cell transistors and in a plurality of rear contact holes, the plurality of rear contact holes being defined by the device isolation layer;
a buried interconnector in a recess region that is at least partially defined by the device isolation layer, the buried interconnector extending in a first horizontal direction or a second horizontal direction and connected to a first rear contact and a second rear contact among the plurality of rear contacts;
a buried insulating layer in the recess region and on a bottom surface of the buried interconnector; and
a rear wiring layer on a bottom surface of the device isolation layer and on a bottom surface of the buried insulating layer.

2. The integrated circuit device of claim 1, wherein the plurality of cell transistors comprises:
a plurality of semiconductor patterns apart from one another in a vertical direction;
a plurality of gate electrodes at least partially surrounding the plurality of semiconductor patterns and extending in the second horizontal direction; and
a plurality of source/drain regions located on both sides of each of the plurality of gate electrodes.

3. The integrated circuit device of claim 2, wherein the first rear contact is connected to a first source/drain region among the plurality of source/drain regions, and
wherein the second rear contact is connected to a first gate electrode among the plurality of gate electrodes.

4. The integrated circuit device of claim 2, wherein the first rear contact is connected to a first source/drain region among the plurality of source/drain regions, and
wherein the second rear contact is connected to a second source/drain region among the plurality of source/drain regions.

5. The integrated circuit device of claim 2, wherein the first rear contact is connected to a first gate electrode among the plurality of gate electrodes, and
wherein the second rear contact is connected to a second gate electrode among the plurality of gate electrodes.

6. The integrated circuit device of claim 2, wherein
the first rear contact is connected to a first source/drain region among the plurality of source/drain regions;
the second rear contact is connected to a second source/drain region among the plurality of source/drain regions; and
the plurality of rear contacts further comprises a third rear contact connected to a first gate electrode among the plurality of gate electrodes, and
wherein the buried interconnector comprises
a first buried interconnector between the first rear contact and the second rear contact and connected to the first rear contact and the second rear contact; and
a second buried interconnector between the first buried interconnector and the third rear contact and connected to the first buried interconnector and to the third rear contact.

7. The integrated circuit device of claim 6, wherein the first buried interconnector extends in the second horizontal direction, and the second buried interconnector extends in the first horizontal direction, and
wherein the first buried interconnector and the second buried interconnector collectively have a T-shaped horizontal cross-sectional shape.

8. The integrated circuit device of claim 6, wherein a top surface of the first buried interconnector is at a higher vertical level than a top surface of the second buried interconnector, and a bottom surface of the first buried interconnector is coplanar with a bottom surface of the second buried interconnector.

9. The integrated circuit device of claim 6, wherein a top surface of the first buried interconnector is at a lower vertical level than a top surface of the second buried interconnector, and
wherein a bottom surface of the first buried interconnector is coplanar with a bottom surface of the second buried interconnector.

10. The integrated circuit device of claim 1, wherein the buried insulating layer at least partially vertically overlaps with the buried interconnector.

11. The integrated circuit device of claim 1, wherein the bottom surface of the buried interconnector is apart from a top surface of the rear wiring layer in a vertical direction, and
wherein at least part of the buried insulating layer is between the bottom surface of the buried interconnector and the top surface of the rear wiring layer.

12. The integrated circuit device of claim 1, wherein a top surface of the buried interconnector is at a lower vertical level than a top surface of the device isolation layer, and
wherein the bottom surface of the buried interconnector is at a higher vertical level than the bottom surface of the device isolation layer.

13. An integrated circuit device, comprising:
a plurality of cell transistors including
a plurality of semiconductor patterns apart from one another in a vertical direction;
a plurality of gate electrodes at least partially surrounding the plurality of semiconductor patterns and extending in a horizontal direction; and
a plurality of source/drain regions located on both sides of each of the plurality of gate electrodes; and
a rear wiring structure on bottom surfaces of the plurality of cell transistors, the rear wiring structure including
a device isolation layer on bottom surfaces of the plurality of cell transistors;
a plurality of rear contacts electrically connected to the plurality of cell transistors and in a plurality of rear contact holes, the rear contact holes at least partially defined by the device isolation layer;
a buried interconnector in a recess region, the recess region at least partially defined by the device isolation layer, the buried interconnector connected to a first rear contact and to a second rear contact among the plurality of rear contacts;
a buried insulating layer in the recess region and on a bottom surface of the buried interconnector; and
a rear wiring layer on a bottom surface of the device isolation layer and on a bottom surface of the buried insulating layer.

14. The integrated circuit device of claim 13, wherein the buried insulating layer at least partially vertically overlaps with the first rear contact, the second rear contact, and the buried interconnector.

15. The integrated circuit device of claim 14, wherein a bottom surface of the first rear contact, a bottom surface of the second rear contact, and the bottom surface of the buried interconnector are coplanar with one another, and
wherein a top surface of the buried insulating layer contacts a bottom surface of the first rear contact, a bottom surface of the second rear contact, and the bottom surface of the buried interconnector.

16. The integrated circuit device of claim 13, wherein
the first rear contact is connected to a first source/drain region among the plurality of source/drain regions;
the second rear contact is connected to a second source/drain region among the plurality of source/drain regions; and
the plurality of rear contacts further comprises a third rear contact that is connected to a first gate electrode among the plurality of gate electrodes, and
wherein the buried interconnector comprises
a first buried interconnector between the first rear contact and the second rear contact and connected to the first rear contact and the second rear contact; and
a second buried interconnector between the first buried interconnector and the third rear contact and connected to the first buried interconnector and the third rear contact.

17. The integrated circuit device of claim 16, wherein a top surface of the first buried interconnector is at a higher vertical level than a top surface of the second buried interconnector, and a bottom surface of the first buried interconnector is coplanar with a bottom surface of the second buried interconnector.

18. The integrated circuit device of claim 13, wherein a top surface of the buried interconnector is at a lower vertical level than a top surface of the device isolation layer, and
wherein the bottom surface of the buried interconnector is at a higher vertical level than the bottom surface of the device isolation layer.

19. An integrated circuit device, comprising:
a plurality of semiconductor patterns apart from one another in a vertical direction;
a plurality of gate electrodes at least partially surrounding the plurality of semiconductor patterns and extending in a horizontal direction;
a plurality of source/drain regions located on both sides of each of the plurality of gate electrodes;
a device isolation layer on a bottom surface of the plurality of source/drain regions and a on bottom surface the plurality of gate electrodes;
a plurality of rear contacts respectively arranged in a plurality of rear contact holes passing through the device isolation layer, the plurality of rear contacts including
a first rear contact connected to a first source/drain region among the plurality of source/drain regions,
a second rear contact connected to a second source/drain region among the plurality of source/drain regions, and
a third rear contact connected to a first gate electrode among the plurality of gate electrodes;
a buried interconnector in a recess region and connected to the first to third rear contacts, the recess region at least partially defined by the device isolation layer, the buried interconnector including
a first buried interconnector between the first rear contact and the second rear contact and connected to the first rear contact and the second rear contact, and
a second buried interconnector between the first buried interconnector and the third rear contact and connected to the first buried interconnector and the third rear contact; and
a buried insulating layer in the recess region and on a bottom surface of the buried interconnector.

20. The integrated circuit device of claim 19, wherein a bottom surface of the first rear contact, a bottom surface of the second rear contact, and the bottom surface of the buried interconnector are coplanar with one another, and
wherein a bottom surface of the first rear contact, a bottom surface of the second rear contact, and the bottom surface of the buried interconnector are at a higher vertical level than a bottom surface of the device isolation layer.
